(19) United States
(12) Patent Application Publication
(10) Pub. No.: US 2026/0231414 A1
(43) Pub. Date: Aug. 6, 2026

(54) SEMICONDUCTOR DEVICE AND MANUFACTURING METHOD THEREOF

(71) Applicant: Kioxia Corporation, Tokyo (JP)

(72) Inventors: Mitsuhiko NODA, Kuwana (JP); Masayoshi TAGAMI, Kuwana (JP); Ryuta MIZUMOTO, Yokkaichi (JP); Susumu HASHIMOTO, Kuwana (JP)

(73) Assignee: Kioxia Corporation, Tokyo (JP)

(21) Appl. No.: 19/410,262

(22) Filed: Dec. 5, 2025

(30) Foreign Application Priority Data
Feb. 3, 2025 (JP) 2025-016071
Apr. 15, 2025 (JP) 2025-067055
Jul. 29, 2025 (CN) 202511046751.1
Jul. 31, 2025 (TW) 114129197

(51) Int. Cl. H10B 43/27; H10B 43/10; H10B 43/35; H10B 43/40; H10D 30/01; H10D 30/69; H10W 72/90; H10W 90/00

(52) U.S. Cl. CPC H10B 43/27; H10B 43/10; H10B 43/35; H10B 43/40; H10D 30/0413; H10D 30/693; H10W 72/90; H10W 90/792

(57) ABSTRACT

A device includes a stacked-body including conductors and insulators stacked in a first-direction. A first insulator is located in the first-direction to the stacked-body. Third-lines include first-lines and second-lines. The third-lines are located in the first-direction to the first insulator, extend in a second-direction, and are arrayed in a third-direction. A fifth-line is located in the first-direction to a fourth-line being one of the first-lines. A first contact connects the fourth-line and the fifth-line. A second insulator is located between a sixth-line and the fourth-line. The sixth-line is another one of the first-lines and is adjacent to the fourth-line. A third insulator is located in the first-direction to the first insulator, and has an air gap between adjacent two of the second-lines. The first contact and the second insulator are located in a first region. The third insulator is located in a second region different from the first region.

### CROSS REFERENCE TO RELATED APPLICATIONS

This application is based upon and claims the benefit of priority from the prior Japanese Patent Application No. 2025-016071 filed on February 3, 2025, the prior Japanese Patent Application No. 2025-067055 filed on April 15, 2025, the prior Chinese Patent Application No.202511046751.1 filed on July 29, 2025, and the prior Taiwan Patent Application No. 114129197 filed on July 31, 2025, the entire contents of which are incorporated herein by reference.

### FIELD

The embodiments of the present invention relate to a semiconductor device and a manufacturing method thereof.

### BACKGROUND

Some of semiconductor memory devices such as a NAND flash memory have a three-dimensional memory cell array where a plurality of memory cells are arranged three-dimensionally. With downscaling of the memory cell array, spaces between adjacent lines are narrowed. This may cause an increase in the parasitic capacitances between lines.

### BRIEF DESCRIPTION OF THE DRAWINGS

FIG. 1 is a sectional view illustrating a configuration example of a semiconductor memory device according to a first embodiment;

FIG. 2 is a schematic plan view illustrating a stacked body;

FIG. 3 is a schematic sectional view illustrating an example of memory cells of a three-dimensional structure;

FIG. 4 is a schematic sectional view illustrating an example of memory cells of a three-dimensional structure;

FIG. 5 is a schematic plan view illustrating a configuration example of bit lines and a peripheral region according to the first embodiment;

FIG. 6 is a plan view illustrating an example of an arrangement relation of the bit lines and via contacts in a via formation region;

FIG. 7 is a sectional view illustrating a configuration example of bit lines and a part peripheral thereto in an air gap region;

FIG. 8 is a sectional view illustrating a configuration example of bit lines and a part peripheral thereto in a buried region;

FIG. 9 is a sectional view illustrating a configuration example of the peripheral region;

FIG. 10 is a sectional view illustrating one example of a manufacturing method of the semiconductor memory device according to the first embodiment;

FIG. 11 is a sectional view illustrating one example of the manufacturing method of the semiconductor memory device in continuation from FIG. 10;

FIG. 12 is a sectional view illustrating one example of the manufacturing method of the semiconductor memory device in continuation from FIG. 11;

FIG. 13 is a sectional view illustrating one example of the manufacturing method of the semiconductor memory device in continuation from FIG. 12;

FIG. 14 is a sectional view illustrating one example of the manufacturing method of the semiconductor memory device in continuation from FIG. 13;

FIG. 15 is a sectional view illustrating one example of the manufacturing method of the semiconductor memory device in continuation from FIG. 14;

FIG. 16 is a sectional view illustrating one example of the manufacturing method of the semiconductor memory device in continuation from FIG. 15;

FIG. 17 is a sectional view illustrating one example of the manufacturing method of the semiconductor memory device in continuation from FIG. 16;

FIG. 18 is a sectional view illustrating one example of the manufacturing method of the semiconductor memory device in continuation from FIG. 17;

FIG. 19 is a sectional view illustrating a configuration example of bit lines and a part peripheral thereto in an air gap region of a semiconductor memory device according to a second embodiment;

FIG. 20 is a sectional view illustrating a configuration example of the bit lines and the part peripheral thereto in the air gap region of the semiconductor memory device according to the second embodiment;

FIG. 21 is a sectional view illustrating a configuration example of a peripheral region of the semiconductor memory device according to the second embodiment;

FIG. 22 is a sectional view illustrating one example of a manufacturing method of the semiconductor memory device according to the second embodiment;

FIG. 23 is a sectional view illustrating one example of the manufacturing method of the semiconductor memory device in continuation from FIG. 22;

FIG. 24 is a sectional view illustrating one example of the manufacturing method of the semiconductor memory device in continuation from FIG. 23;

FIG. 25 is a sectional view illustrating one example of the manufacturing method of the semiconductor memory device in continuation from FIG. 24;

FIG. 26 is a sectional view illustrating one example of the manufacturing method of the semiconductor memory device in continuation from FIG. 25;

FIG. 27 is a sectional view illustrating one example of the manufacturing method of the semiconductor memory device in continuation from FIG. 26;

FIG. 28 is a sectional view illustrating one example of the manufacturing method of the semiconductor memory device in continuation from FIG. 27;

FIG. 29 is a sectional view illustrating one example of the manufacturing method of the semiconductor memory device in continuation from FIG. 28;

FIG. 30 is a plan view illustrating a configuration example of a semiconductor memory device according to a third embodiment;

FIG. 31 is a plan view illustrating details of a portion of FIG. 30;

FIG. 32 is a plan view illustrating a configuration example of a semiconductor memory device according to a fourth embodiment;

FIG. 33 is a sectional view illustrating one example of a manufacturing method of the semiconductor memory device according to the fourth embodiment;

FIG. 34 is a sectional view illustrating one example of the manufacturing method of the semiconductor memory device in continuation from FIG. 33;

FIG. 35 is a sectional view illustrating one example of the manufacturing method of the semiconductor memory device in continuation from FIG. 34;

FIG. 36 is a sectional view illustrating a configuration example of a semiconductor memory device according to a modification of the fourth embodiment;

FIG. 37 is a sectional view illustrating a configuration example of the semiconductor memory device according to the modification of the fourth embodiment;

FIG. 38 is a sectional view illustrating a configuration example of the semiconductor memory device according to the modification of the fourth embodiment;

FIG. 39 is a sectional view illustrating a configuration example of the semiconductor memory device according to the modification of the fourth embodiment;

FIG. 40 is a sectional view illustrating a configuration example of a semiconductor memory device according to a fifth embodiment;

FIG. 41 is a sectional view illustrating one example of a manufacturing method of the semiconductor memory device according to the fifth embodiment;

FIG. 42 is a sectional view illustrating one example of the manufacturing method of the semiconductor memory device in continuation from FIG. 41;

FIG. 43 is a sectional view illustrating one example of the manufacturing method of the semiconductor memory device in continuation from FIG. 42;

FIG. 44 is a sectional view illustrating one example of the manufacturing method of the semiconductor memory device in continuation from FIG. 43;

FIG. 45 is a sectional view illustrating one example of the manufacturing method of the semiconductor memory device in continuation from FIG. 44;

FIG. 46 is a block diagram illustrating a configuration example of a semiconductor memory device to which an array chip is applied; and

FIG. 47 is a circuit diagram illustrating one example of a circuit configuration of a memory cell array.

### DETAILED DESCRIPTION

In general, a semiconductor device according to the present embodiment includes a stacked body. The stacked body includes a plurality of conductive layers and a plurality of insulating layers stacked alternately in a first direction. A first insulating film is located in the first direction with respect to the stacked body. Third lines include a plurality of first lines and a plurality of second lines. The third lines are located in the first direction with respect to the first insulating film, extend in a second direction intersecting with the first direction, and are arrayed in a third direction intersecting with the first and second directions. A fifth line is located in the first direction with respect to a fourth line being any one of the plurality of first lines. A first contact electrically connects the fourth line and the fifth line. A second insulating film is located between a sixth line and the fourth line. The sixth line is another one of the first lines and is adjacent to the fourth line. A third insulating film is located in the first direction with respect to the first insulating film, and has an air gap between adjacent two of the plurality of second lines. The first contact and the second insulating film are located in a first region as viewed from the first direction. The third insulating film is located in a second region different from the first region as viewed from the first direction.

Hereinafter, devices of the present disclosure will be described with reference to the drawings.

The present invention is not limited to the embodiments. In the present specification and the drawings, elements identical to those described in the foregoing drawings are denoted by like reference characters and detailed explanations thereof are omitted as appropriate.

### First embodiment

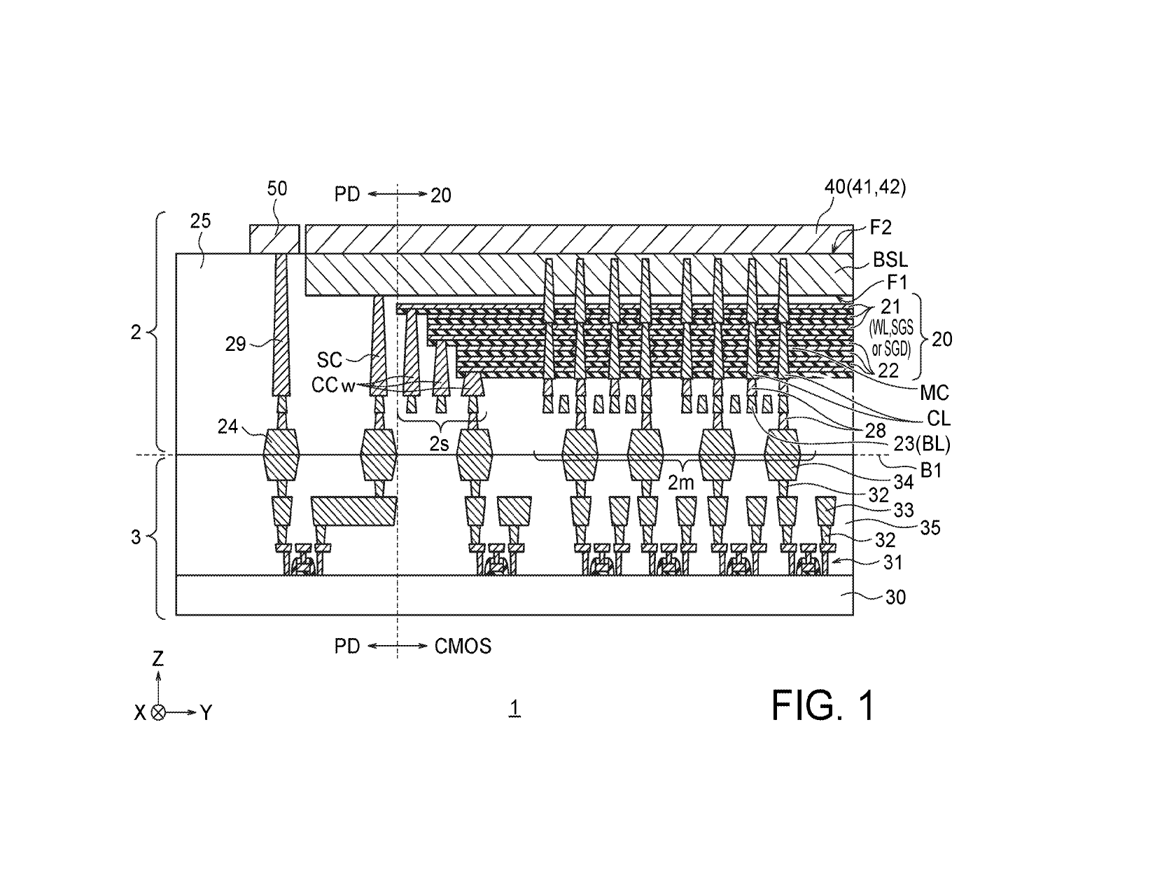

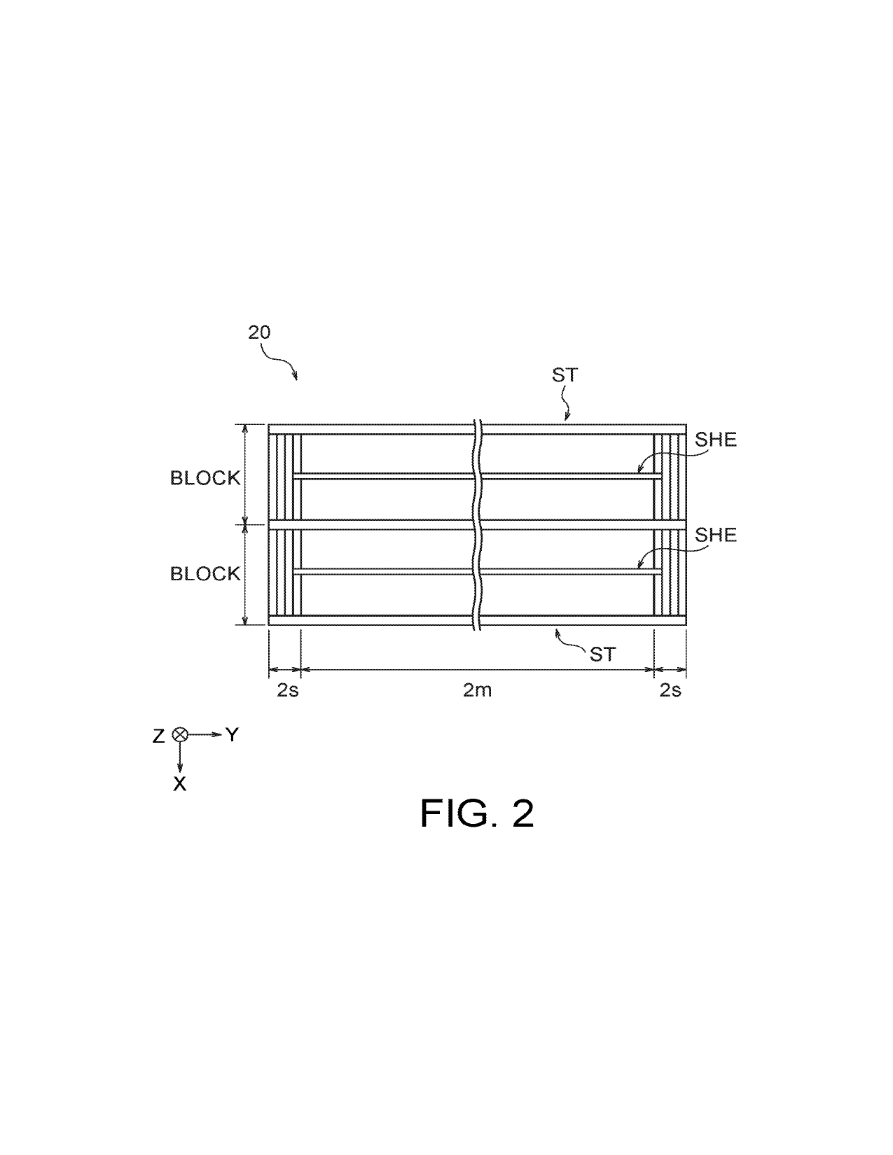

FIG. 1 is a sectional view illustrating a configuration example of a semiconductor memory device 1 according to a first embodiment. Hereinafter, the stacking direction of a stacked body 20 is assumed as a Z direction. One direction intersecting with, for example, orthogonal to the Z direction is assumed as a Y direction. One direction intersecting with, for example, orthogonal to the Z direction and the Y direction is assumed as an X direction. In the present specification, a -Z direction is one example of a first direction. Furthermore, ±X directions are examples of a second direction intersecting with (for example, orthogonal to) the first direction, and ±Y directions are examples of a third direction intersecting with the first and second directions. In FIG. 1, an "upward direction" indicates a +Z direction. However, the "upward direction" indicates the -Z direction in some of FIG. 2 and subsequent drawings.

The semiconductor memory device 1 includes an array chip 2 having a memory cell array, and a CMOS (Complementary Metal Oxide Semiconductor) chip 3 having a CMOS circuit. The array chip 2 and the CMOS chip 3 are bonded to each other on a bonding face B1 and are electrically connected to each other with lines joined on the bonding face B1. FIG. 1 illustrates a state where the array chip 2 is located on the CMOS chip 3.

The CMOS chip 3 includes a substrate 30, transistors 31, via contacts 32, lines 33 and 34, and an interlayer insulating film 35.

The substrate 30 is, for example, a semiconductor substrate such as a silicon substrate. The transistors 31 are NMOS or PMOS transistors provided on the substrate 30. For example, transistors 31 constitute a CMOS circuit that controls the memory cell array of the array chip 2. A plurality of transistors 31 constitute a logic circuit such as a sense amplifier, a row decoder, or a column decoder. Semiconductor elements such as a resistive element and a capacitive element, other than the transistors 31 may be formed on the substrate 30.

Each of the via contacts 32 electrically connects between a transistor 31 and a line 33 or between a line 33 and a line 34. The lines 33 and 34 constitute a multilayer interconnection structure in the interlayer insulating film 35. The lines 34 are embedded in the interlayer insulating film 35 and are exposed on the surface of the interlayer insulating film 35 to be substantially flush with the surface. The lines 33 and 34 are electrically connected to the transistors 31 and the like. For example, a metal such as copper or tungsten is used as the via contacts 32, and the lines 33 and 34. The interlayer insulating film 35 coats and protects the transistors 31, the via contacts 32, and the lines 33 and 34. For example, an insulating film such as a silicon dioxide film is used as the interlayer insulating film 35.

The array chip 2 includes the stacked body 20, columnar bodies CL, slits ST (LI), a source layer BSL, a metallic layer 40, contact plugs CCw, contact plugs 29, bonding pads 50, and an interlayer insulating film 25.

The stacked body 20 is provided in the upward direction of the transistors 31 and is positioned in the +Z direction with respect to the substrate 30. The stacked body 20 is configured by alternately stacking a plurality of electrode films 21 and a plurality of insulating films 22 along the Z direction. The stacked body 20 constitutes the memory cell array. For example, a conductive metal such as tungsten is used for the electrode films 21. As the insulating films 22, insulating films such as silicon dioxide films are used, for example. The insulating films 22 insulate the electrode films 21 from each other. That is, the electrode films 21 are stacked in a mutually insulated state. The numbers of stacked layers of the electrode films 21 and the insulating films 22 can be optionally selected. The insulating films 22 may be, for example, porous insulating films or air gaps.

One or a plurality of the electrode films 21 at the upper end and one or a plurality of the electrode films 21 at the lower end of the stacked body 20 in the Z direction function as source-side selection gates SGS and drain-side selection gates SGD, respectively. Electrode films 21 between the source-side selection gates SGS and the drain-side selection gates SGD function as word lines WL. The word lines WL are gate electrodes of memory cells MC. The source-side selection gates SGS are gate electrodes of source-side selection transistors. The drain-side selection gates SGD are gate electrodes of drain-side selection transistors. The source-side selection gates SGS are provided in an upper region of the stacked body 20. The drain-side selection gates SGD are provided in a lower region of the stacked body 20. The upper region indicates a region of the stacked body 20 on a side far from the CMOS chip 3 (a side close to the metallic layer 40), and the lower region indicates a region of the stacked body 20 on a side close to the CMOS chip 3.

The semiconductor memory device 1 includes a plurality of memory cells MC connected in series between each of the source-side selection transistors and a corresponding drain-side selection transistor. A structure in which a source-side selection transistor, memory cells MC, and a drain-side selection transistor are connected in series is referred to as "memory string" or "NAND string". A memory string is, for example, connected to a bit line BL through a via contact 28. The bit lines BL are lines 23 provided below the stacked body 20 and extending in the X direction (the front-back direction of the drawing in FIG. 1).

A plurality of columnar bodies CL are provided in the stacked body 20. The columnar bodies CL extend in the stacked body 20 to penetrate through the stacked body 20 in the stacking direction (the Z direction) of the stacked body 20 and are provided from associated via contacts 28 connected to the bit lines BL to the source layer BSL. An internal structure of the columnar bodies CL will be described later. In the present embodiment, each of the columnar bodies CL is formed in two tiers in the Z direction. However, there is no problem with the columnar bodies CL each formed in one tier. Alternatively, each of the columnar bodies CL may be formed in three or more tiers.

Although not illustrated in FIG. 1, a plurality of slits ST (see FIG. 2) are provided in the stacked body 20. The slits ST extend in the Y direction and penetrate through the stacked body 20 in the stacking direction (the Z direction) of the stacked body 20. Each of the slits ST is filled with an insulating film such as a silicon dioxide film and the insulating film is configured in a plate shape. The slits ST electrically separate the electrode films 21 of the stacked body 20. It is alternatively possible that the inner wall of each of the slits ST is coated with an insulating film such as a silicon dioxide film and that a conductive material is further embedded in the inner side of the insulating film. In this case, the conductive material can also function as a source line reaching the source layer BSL.

The source layer BSL is located on the stacked body 20. The source layer BSL is provided corresponding to the stacked body 20. The source layer BSL has a first face F1, and a second face F2 on the opposite side to the first face F1. The stacked body 20 (the memory cell array) is located on the side of the first face F1 of the source layer BSL, and the metallic layer 40 is located on the side of the second face F2. The metallic layer 40 includes a source line 41 and a power line 42. The source layer BSL is connected in common to one ends of columnar bodies CL and provides the columnar bodies CL in the same memory cell array 2m with a common source potential. That is, the source layer BSL functions as a common source electrode of the memory cell array 2m. For example, a conductive material such as doped polysilicon is used as the source layer BSL. For example, a metallic material such as copper, aluminum, or tungsten having a lower resistance than that of the source layer BSL is used as the metallic layer 40. 2s denotes a stepped portion of the electrode films 21 provided to connect the contact plugs CCw to the associated electrode films 21. The stepped portion 2s will be described later with reference to FIG. 2.

Meanwhile, the bonding pads 50 are provided in the upward direction of the stacked body 20 and in a region where the source layer BSL is not provided. The bonding pads 50 are connected to metallic wires (not illustrated) or the like and receive power supply or signals from outside the semiconductor memory device 1. The bonding pads 50 are each provided to be connected to one end of a contact plug 29 in the Z direction. The bonding pads 50 are each connected to a transistor 31 of the CMOS chip 3 through a contact plug 29, a line 24, and a line 34. Accordingly, external power supplied from a bonding pad 50 is supplied to the associated transistor 31. Alternatively, a signal is supplied to a transistor 31 or the memory cell array 2m via the associated bonding pad 50.

The contact plugs CCw are provided in an outer edge portion of the stacked body 20 and extend in the Z direction in the interlayer insulating film 25. Each of the contact plugs CCw is electrically connected between an electrode film 21 (a word line WL) and a line 24. The contact plugs CCw are provided at the stepped portions 2s formed in the manner of stairs at ends of the stacked body 20 and are each electrically connected to the associated electrode film 21. The contact plugs CCw are provided to transmit a word line voltage from the CMOS chip 3 to the associated electrode films 21. For example, a metal such as copper or tungsten is used as the contact plugs CCw.

The contact plugs 29 are located in a peripheral region PD peripheral to a region where the stacked body 20 is formed and extend in the Z direction in the interlayer insulating film 25. The contact plugs 29 are contact plugs each located from a line 24 to an associated bonding pad 50. The contact plugs 29 are simultaneously formed in the same process as that of the contact plugs CCw connected to the word lines WL.

The contact plugs 29 are each electrically connected between a bonding pad 50 and a line 24. Each of the contact plugs 29 is used to supply a power voltage or a signal from the associated bonding pad 50 to the array chip 2 or the CMOS chip 3. For example, a metal such as copper or tungsten is used as the contact plugs 29. The power voltage is, for example, a power voltage VDD, or a reference voltage (for example, a ground voltage) VSS lower than the power voltage VDD. The signal may be a control signal from outside, or may be data to be written or read data.

In the present embodiment, the array chip 2 and the CMOS chip 3 are individually formed and are bonded to each other on the bonding face B1. Therefore, the transistors 31 are not provided in the array chip 2. The stacked body 20 (the memory cell array) is not provided in the CMOS chip 3. The transistors 31 and the stacked body 20 are both located on the side of the first face F1 of the source layer BSL. The transistors 31 are located on the opposite side to the second face F2 where the metallic layer 40 is located.

The via contacts 28, the lines 23, and the lines 24 are located below the stacked body 20. The lines 23 and 24 are embedded in the interlayer insulating film 25. The lines 24 are exposed on the surface of the interlayer insulating film 25 to be substantially flush with the surface. The lines 23 and 24 are electrically connected to semiconductor bodies 210 of the columnar bodies CL, or the like. For example, a metal such as copper or tungsten is used as the via contacts 28, the lines 23, and the lines 24. The interlayer insulating film 25 coats and protects the stacked body 20, the via contacts 28, the lines 23, and the lines 24. For example, an insulating film such as a silicon dioxide film is used as the interlayer insulating film 25.

The interlayer insulating film 25 and the interlayer insulating film 35 are bonded to each other on the bonding face B1. Associated therewith, the lines 24 and the lines 34 are joined to each other on the bonding face B1 to be substantially flush therewith. Accordingly, the array chip 2 and the CMOS chip 3 are electrically connected to each other via the lines 24 and the lines 34.

FIG. 2 is a schematic plan view illustrating the stacked body 20. The stacked body 20 includes the stepped portions 2s and the memory cell array 2m. The stepped portions 2s are located, for example, at ends of the stacked body 20. The memory cell array 2m is sandwiched or surrounded by the stepped portions 2s. The slits ST (LI) are provided from the stepped portion 2s at one end of the stacked body 20 through the memory cell array 2m to the stepped portion 2s at the other end of the stacked body 20. Slits SHE are provided at least on the memory cell array 2m. The slits SHE are shallower in the Z direction than the slits ST (LI) and extend substantially in parallel to the slits ST (LI). The slits SHE electrically separate the electrode films 21 for each of the drain-side selection gates SGD. The slits ST may be source lines LI electrically connected to the source layer BSL while electrically separated from the electrode films 21 of the stacked body 20. That is, the slits ST may be source lines LI electrically separated from the electrode films 21 of the stacked body 20 constituting the memory cell array and electrically connected to the source layer BSL.

A portion of the stacked body 20 sandwiched by two slits ST illustrated in FIG. 2 is referred to as "block (BLOCK)". A block constitutes, for example, a minimum unit of data erasing. A slit SHE is provided in each block. The stacked body 20 between a slit ST and a slit SHE is referred to as "finger". The drain-side selection gates SGD are divided for each finger. Accordingly, at the time of writing and reading data, one finger in a block can be brought to a selected state by the associated drain-side selection gate SGD.

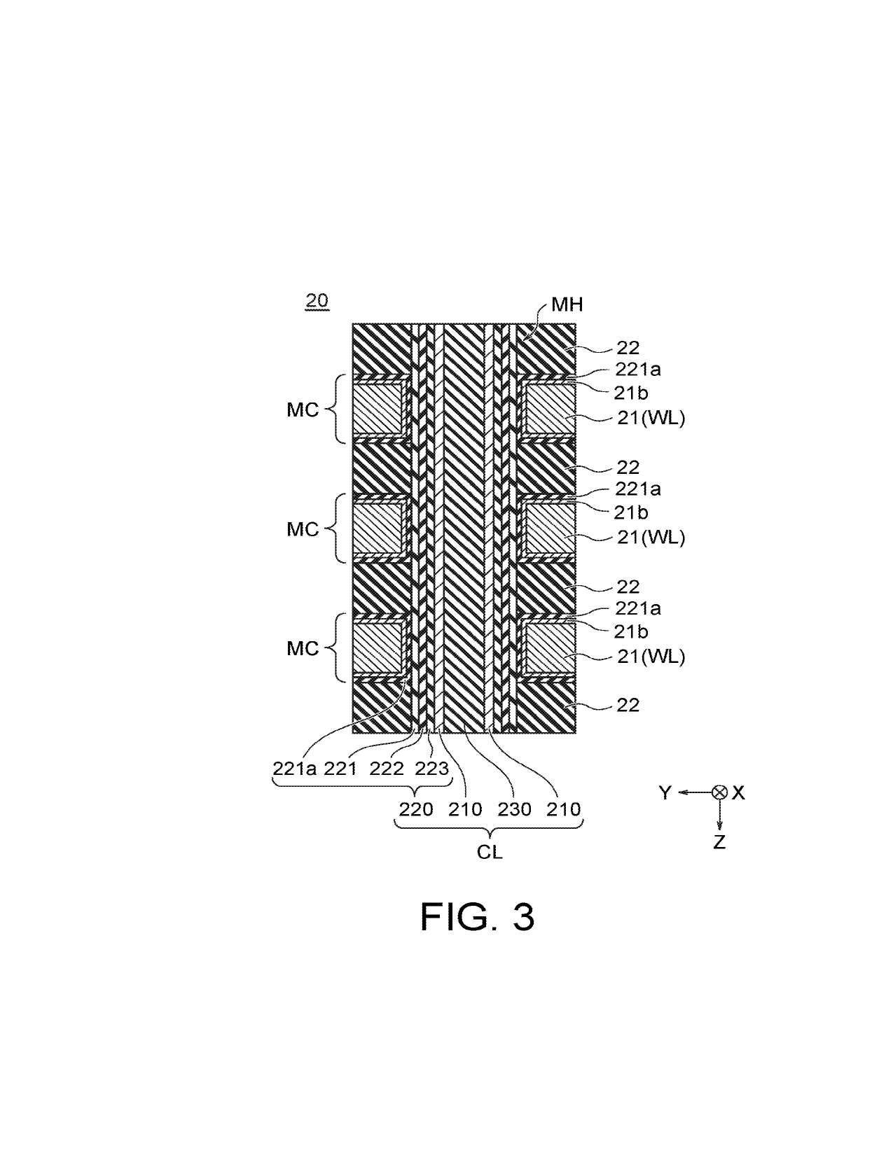

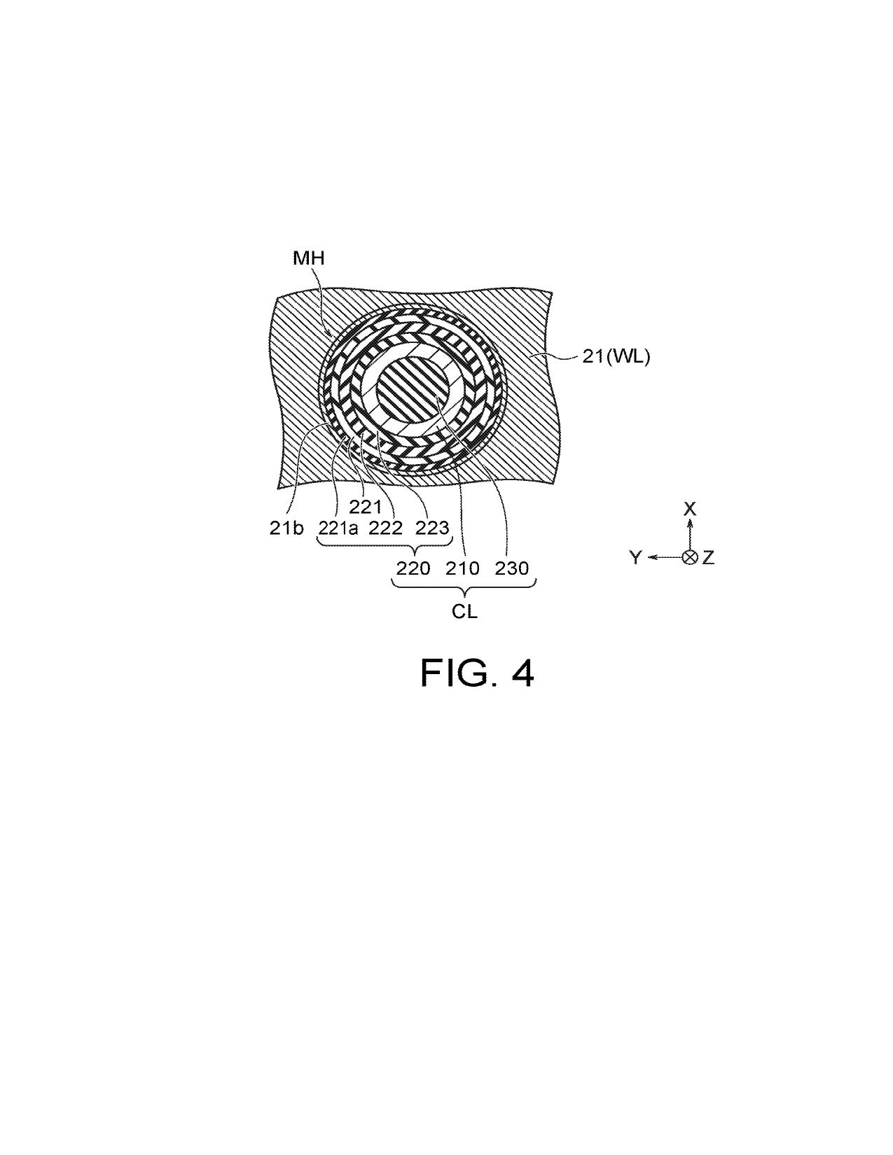

FIGS. 3 and 4 are schematic sectional views illustrating an example of memory cells of a three-dimensional structure. The columnar bodies CL are each provided in a memory hole MH formed in the stacked body 20. Each of the columnar bodies CL penetrates through the stacked body 20 from one end part of the stacked body 20 along the Z direction to be provided in the stacked body 20 and the source layer BSL. Each of the columnar bodies CL includes the semiconductor body 210, a memory film 220, and a core layer 230. Each columnar body CL includes the core layer 230 located at a central part thereof, the semiconductor body (a semiconductor member) 210 located around the core layer 230, and the memory film 220 located around the semiconductor body 210. The semiconductor body 210 extends in the stacked body 20 in the stacking direction (the Z direction). The semiconductor body 210 is electrically connected to the source layer BSL. The memory film 220 is located between the semiconductor body 210 and the electrode films 21 and has charge capturing parts. A plurality of the columnar bodies CL each selected from each finger are connected in common to one bit line BL through the associated via contacts 28 in FIG. 1. Each of the columnar bodies CL is provided, for example, in a region of the memory cell array 2m.

As illustrated in FIG. 4, the shape of each of the memory holes MH in an X-Y plane is, for example, circular or elliptic. A block insulating film 221a constituting a part of the memory film 220 may be provided between each of the electrode films 21 and adjacent insulating films 22. The block insulating film 221a is, for example, a silicon oxide or a metal oxide. One example of the metal oxide is an aluminum oxide. A barrier film 21b may be provided between each of the electrode films 21 and adjacent insulating films 22 and between each of the electrode films 21 and the memory film 220. The barrier film 21b is, for example, a laminated film including titanium nitride and titanium when the electrode films 21 are tungsten. The block insulating film 221a suppresses back tunneling of charges from the electrode films 21 to the memory film 220. The barrier film 21b improves adhesion between the electrode films 21 and the block insulating film 221a.

The shape of the semiconductor body 210 is, for example, a bottomed tube. For example, polysilicon is used as the semiconductor body 210. The semiconductor body 210 is, for example, undoped silicon. Alternatively, the semiconductor body 210 may be p-type silicon. The semiconductor body 210 functions as channels of the drain-side selection transistors, the memory cells MC, and the source-side selection transistors. That is, the memory cells MC each have a memory region between the semiconductor body 210 and an electrode film 21 functioning as a word line WL and are stacked in the Z direction. One ends of the semiconductor bodies 210 in the same memory cell array 2m are electrically connected in common to the source layer BSL.

The memory film 220 includes, for example, a cover insulating film 221, a charge capturing film 222, a tunnel insulating film 223, and the block insulating film 221a. A portion of the memory film 220 other than the block insulating film 221a is located between the inner wall of the memory hole MH and the semiconductor body 210. The shape of the memory film 220 is, for example, tubular. Each of the charge capturing film 222 and the tunnel insulating film 223 extends in the Z direction.

The cover insulating film 221 is located between the insulating films 22 and the charge capturing film 222 and between the block insulating film 221a and the charge capturing film 222. The cover insulating film 221 includes, for example, a silicon oxide. The cover insulating film 221 protects the charge capturing film 222 from being etched when sacrificial films (not illustrated) are replaced by the electrode films 21 (in a replacement process). In a case where the replacement process is not used to form the electrode films 21, it is possible that the cover insulating film 221 is not provided.

The charge capturing film 222 is located between the cover insulating film 221 and the tunnel insulating film 223. The charge capturing film 222 includes, for example, a silicon nitride and has a trap site that traps charges in the film. Portions of the charge capturing film 222 sandwiched between the electrode films 21 functioning as the word lines WL and the semiconductor body 210 function as the charge capturing parts and constitute the memory regions of the memory cells MC. A threshold voltage of each of the memory cells MC varies according to whether there are charges in the associated charge capturing part or the quantity of charges captured in the charge capturing part. Each of the memory cells MC thus retains information.

The tunnel insulating film 223 is located between the semiconductor body 210 and the charge capturing film 222. The tunnel insulating film 223 includes, for example, a silicon oxide, or a silicon oxide and a silicon nitride. The tunnel insulating film 223 is a potential barrier between the semiconductor body 210 and the charge capturing film 222. For example, when electrons are injected from the semiconductor body 210 to the charge capturing film 222 (a write operation) and when positive holes are injected from the semiconductor body 210 to the charge capturing film 222 (an erase operation), the electrons and the positive holes each pass through (tunnel) the potential barrier of the tunnel insulating film 223.

The core layer 230 fills the internal space of the tubular semiconductor body 210. The shape of the core layer 230 is, for example, columnar. For example, an insulating material such as a silicon oxide is used as the core layer 230.

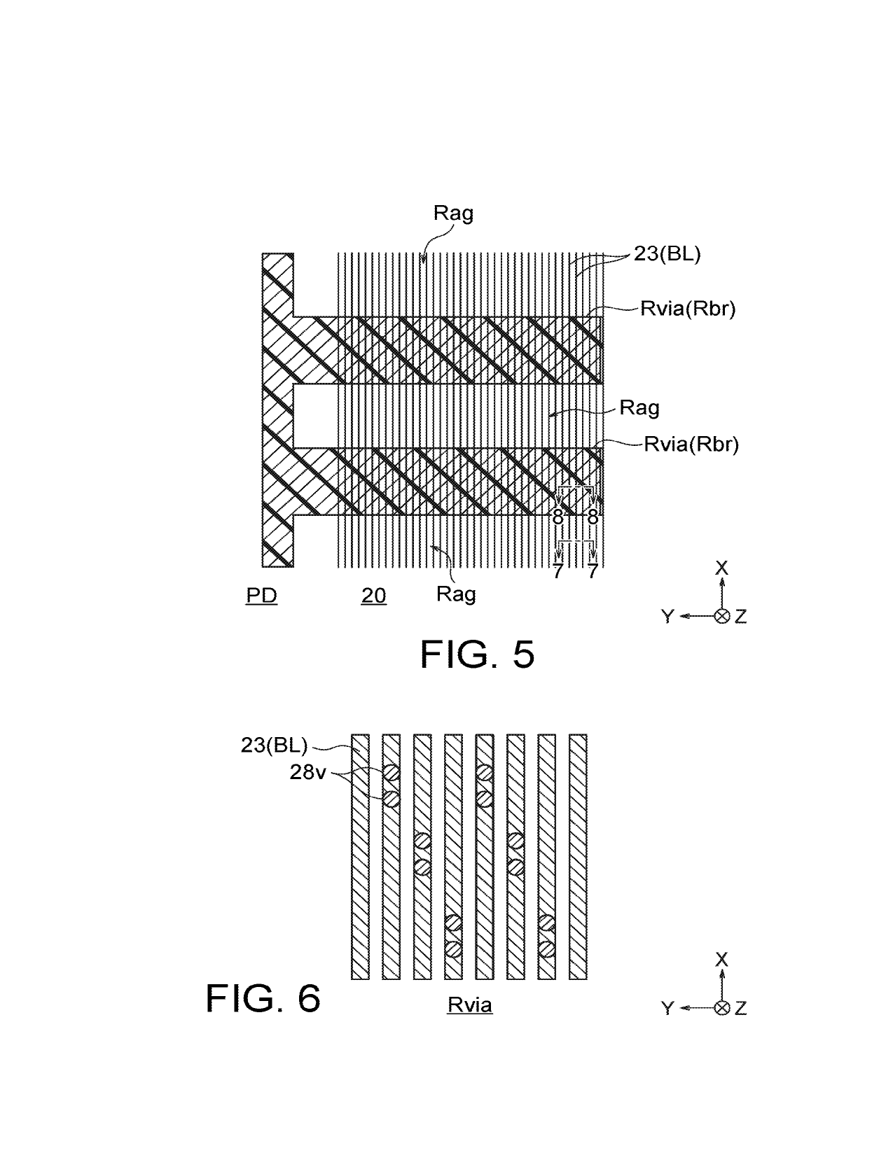

FIG. 5 is a schematic plan view illustrating a configuration example of the bit lines BL and the peripheral region PD according to the first embodiment. FIG. 6 is a plan view illustrating an example of an arrangement relation of the bit lines BL and via contacts 28v in a via formation region Rvia. Hereinafter, the -Z direction is referred to as the "upward direction" in some cases.

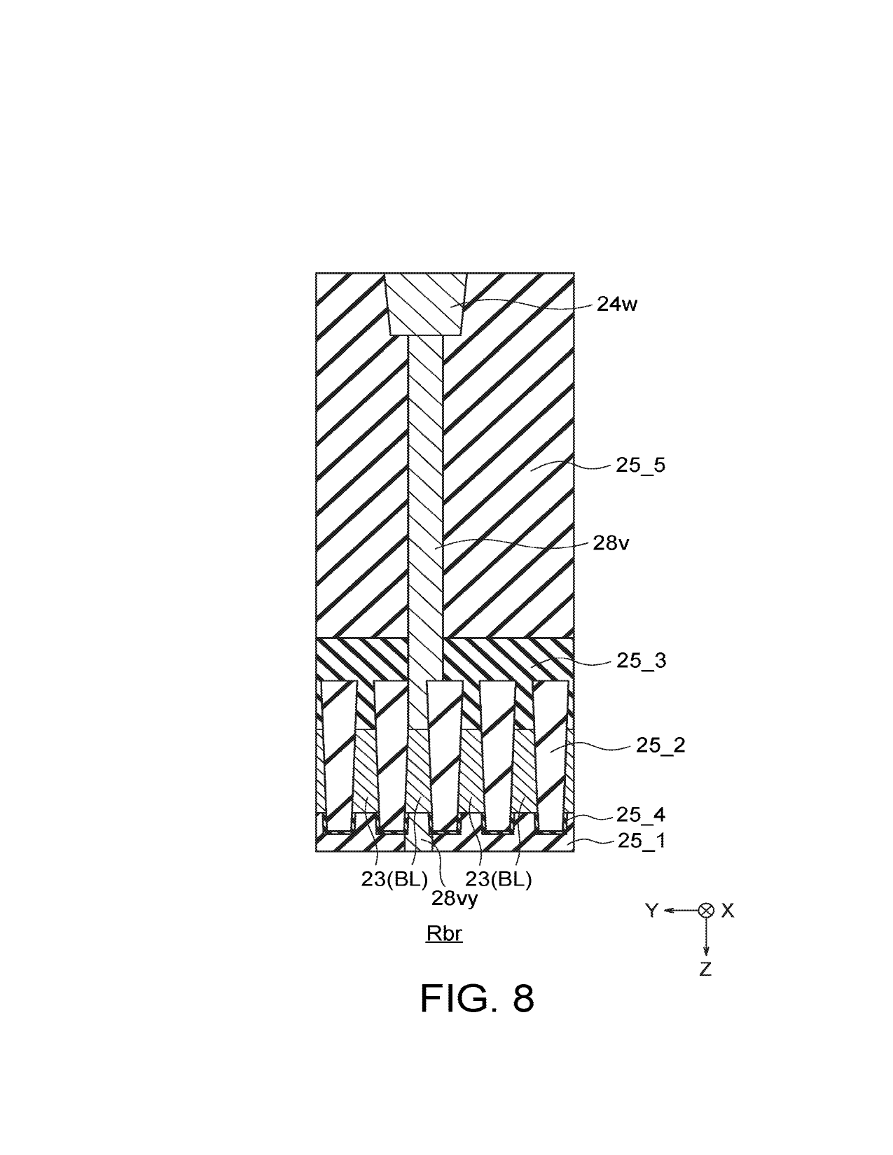

The bit lines BL extend in the X direction and are arrayed in the Y direction. The bit lines BL are not located in the peripheral region PD. The via contacts 28v are each connected between a bit line BL and a line (for example, 24w in FIG. 8) located in the upward direction (in the -Z direction) thereof. The bit lines BL are examples of first lines, second lines, and third lines.

The via formation region Rvia in FIG. 5 is a region where the via contacts 28v are formed. Specifically, the via formation region Rvia is a region including a plane in contact with the bit lines BL at least at the via contacts 28v as viewed from the Z direction. The via formation region Rvia is an example of a first region.

For example, two of the via contacts 28v are provided for each bit line BL as illustrated in FIG. 6 and electrically connect each of the bit lines BL to a different one of the lines 24. The via contacts 28v are arranged to be shifted from each other in the extending direction (the X direction) of the bit lines BL so as not to short-circuit the bit lines BL with each other. Each via formation region Rvia in FIG. 5 is set to cover all the formation places of these via contacts 28v as viewed from the Z direction. A via formation region Rvia is a region including a small margin from via contacts 28v positioned at an upper end, a lower end, a right end, and a left end of the via contacts 28v as viewed from the Z direction. The via contacts 28v are an example of a first contact.

A plurality of the via formation regions Rvia each extend in the Y direction and are arrayed in the X direction. Therefore, the via formation regions Rvia have a shape of stripes. The via formation regions Rvia are connected in the peripheral region PD and are continuous. Only one via formation region Rvia may be provided if the via formation region Rvia covers the formation places of the via contacts 28v as viewed from the Z direction. It is to be noted that the via formation region Rvia partially covers the bit lines BL without covering the whole thereof.

A buried region Rbr in FIG. 5 coincides with a via formation region Rvia where the via contacts 28v are formed as viewed from the Z direction. A buried region Rbr is a region where an insulating material is provided between adjacent ones of the bit lines BL. In each buried region Rbr, the insulating material is substantially buried between adjacent ones of the bit lines BL and there is almost no air gap. The length of the buried regions Rbr of the stacked body 20 in the X direction accounts for, for example, about 30% of the length of each bit line BL. In the X-Y plane, the area of the buried regions Rbr of the stacked body 20 accounts for, for example, about 30% of an area where the bit lines BL are formed in the stacked body 20.

Meanwhile, an air gap region Rag is a region other than the via formation regions Rvia in the region where the bit lines BL are located as viewed from the Z direction. The air gap region Rag is a region where air gaps AG are provided between adjacent ones of the bit lines BL. In the air gap region Rag, the insulating material is not buried between adjacent ones of the bit lines BL and the air gaps AG are left. The length of the air gap region Rag in the stacked body 20 in the X direction accounts for, for example, about 70% of the length of each bit line BL. In the X-Y plane, the area of the air gap region Rag in the stacked body 20 accounts for, for example, about 70% of the area where the bit lines BL are formed in the stacked body 20. The air gap region Rag is an example of a second region.

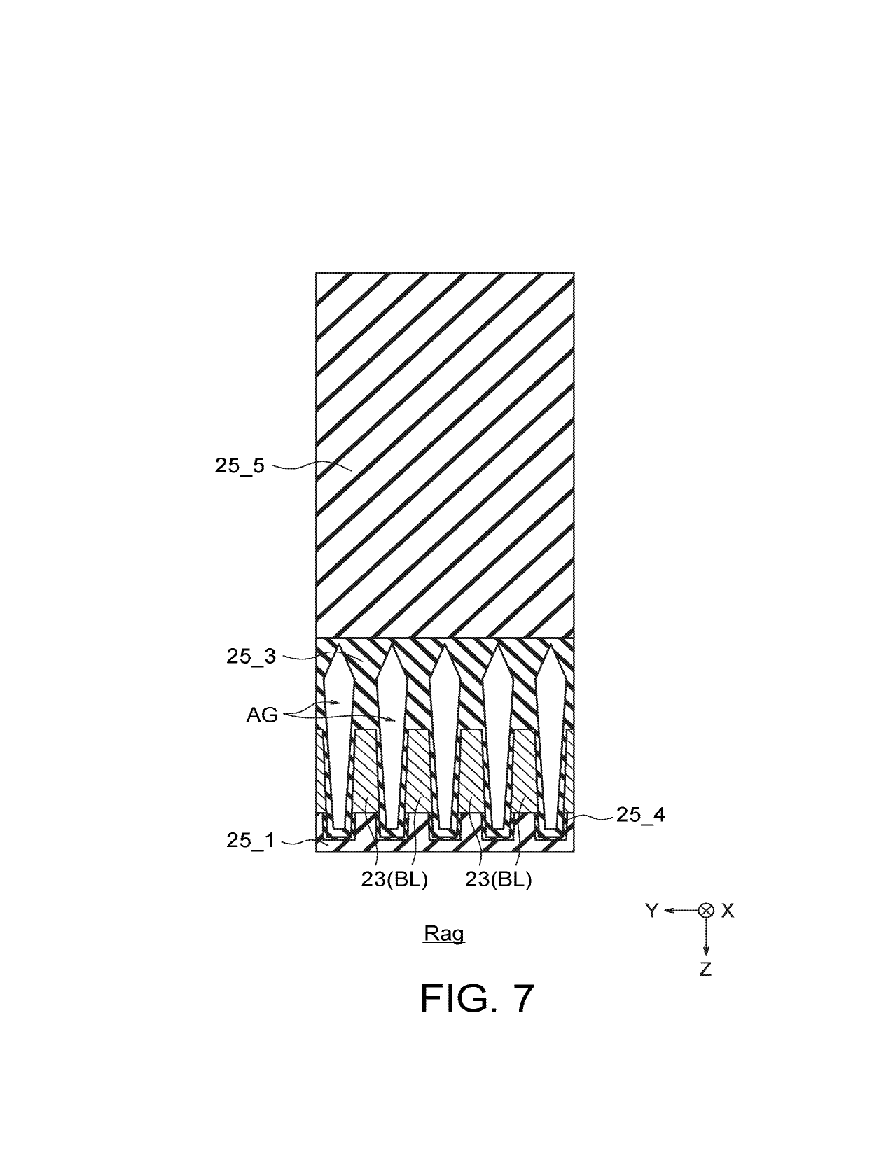

FIG. 7 is a sectional view illustrating a configuration example of the bit lines BL and a part peripheral thereto in the air gap region Rag. FIG. 7 is a sectional view along a line 7-7 in FIG. 5. FIG. 8 is a sectional view illustrating a configuration example of the bit lines BL and a part peripheral thereto in the buried region Rbr. FIG. 8 is a sectional view along a line 8-8 in FIG. 5.

The semiconductor memory device 1 according to the present embodiment includes a first insulating film 25_1, via contacts 28vy, the bit lines BL, a second insulating film 25_2, a third insulating film 25_3, a fourth insulating film 25_4, a fifth insulating film 25_5, the via contacts 28v, lines 24w, and the air gaps AG. The air gaps AG indicate clearances not including a material such as an insulating film and are hollow portions. Air or gas is included in the air gaps AG in some cases.

For example, an insulating material such as a silicon oxide is used as the first insulating film 25_1. The stacked body 20 in FIG. 1 is located below (in the +Z direction) the first insulating film 25_1.

The via contacts 28vy are located in the first insulating film 25_1. Each of the via contacts 28vy is electrically connected between the semiconductor body 210 of a columnar body CL and a bit line BL. Accordingly, the semiconductor body 210 of each columnar body CL is electrically connected to any one of the bit lines BL through the associated via contact 28vy. For example, a conductive material such as tungsten or copper is used as the via contacts 28vy.

The bit lines BL are located in the -Z direction of the first insulating film 25_1. As described above, the bit lines BL extend in the X direction and are arrayed in the Y direction. For example, a conductive material such as tungsten or copper is used as the bit lines BL. In the air gap region Rag in FIG. 7, the bit lines BL are electrically separated from each other by the third insulating film 25_3 and the air gaps AG. In the buried region Rbr in FIG. 8, the bit lines BL are electrically separated from each other by the second insulating film 25_2.

A part between the bit lines BL is filled with the second insulating film 25_2 in the buried region Rbr in FIG. 8. The air gaps AG are intendedly unformed and not provided in the second insulating film 25_2. The second insulating film 25_2 is not provided between the bit lines BL in the air gap region Rag. For example, an insulating material such as a silicon oxide is used as the second insulating film 25_2.

The third insulating film 25_3 as an air gap insulating film is provided on the bit lines BL in the air gap region Rag in FIG. 7. The third insulating film 25_3 is also provided around the air gaps AG and encompasses the air gaps AG. That is, the third insulating film 25_3 is located between the bit lines BL and internally has the air gaps AG. The third insulating film 25_3 is located on the bit lines BL and the second insulating film 25_2 in the buried region Rbr in FIG. 8. For example, an insulating material such as a silicon nitride is used as the third insulating film 25_3.

The fourth insulating film 25_4 is provided to connect ends of adjacent ones of the bit lines BL between the first insulating film 25_1 and the third insulating film 25_3 in the air gap region Rag in FIG. 7. The fourth insulating film 25_4 is provided to connect ends of adjacent ones of the bit lines BL between the first insulating film 25_1 and the second insulating film 25_2 in the buried region Rbr in FIG. 8. The fourth insulating film 25_4 functions as an etching stopper at the time of removing the second insulating film 25_2 later. For example, an insulating material such as a silicon nitride is used as the fourth insulating film 25_4.

The fifth insulating film 25_5 is located on the third insulating film 25_3. For example, an insulating material such as a silicon oxide is used as the fifth insulating film 25_5.

The via contacts 28v are formed in the via formation region Rvia in the buried region Rbr in FIG. 8. Each of the via contacts 28v electrically connects a bit line BL and a line 24w. The via contacts 28v extend in the Z direction in the fifth insulating film 25_5. Each via contact 28v connects one bit line BL to one line 24w without short-circuiting the bit lines BL. For example, a conductive material such as tungsten or copper is used as the via contacts 28v.

The lines 24w are located in the upward direction (the -Z direction) of the bit lines BL and are each located on the associated via contacts 28v. Any of the lines 24w is electrically connected to the corresponding bit line BL through a via contact 28v. For example, a conductive material such as tungsten or copper is used as the lines 24w. The lines 24w are an example of a fifth line.

Each of the air gaps AG is located between adjacent ones of the bit lines BL in the air gap region Rag in FIG. 7. The air gaps AG are not provided between the bit lines BL in the buried region Rbr in FIG. 8. Upper ends of the air gaps AG in the -Z direction are at a position closer to the lines 24w than upper ends of the bit lines BL in the -Z direction. That is, the upper ends of the air gaps AG in the -Z direction are formed at a position higher than the upper ends of the bit lines BL in the -Z direction. Lower ends of the air gaps AG in the +Z direction are at a position closer to the first insulating film 25_1 than lower ends of the bit lines BL in the +Z direction. That is, each air gap AG is longer than each bit line BL in the ±Z directions and is provided over the entire bit line BL.

The third insulating film 25_3 is provided on the sidewall of each of the bit lines BL. Therefore, the third insulating film 25_3 is located between the sidewalls of the bit lines BL and the air gaps AG. The third insulating film 25_3 is also located between the side and bottom surfaces of the first insulating film 25_1 and the air gaps AG. That is, the air gaps AG are surrounded by the third insulating film 25_3. Accordingly, the parasitic capacitances between the bit lines BL can be effectively reduced.

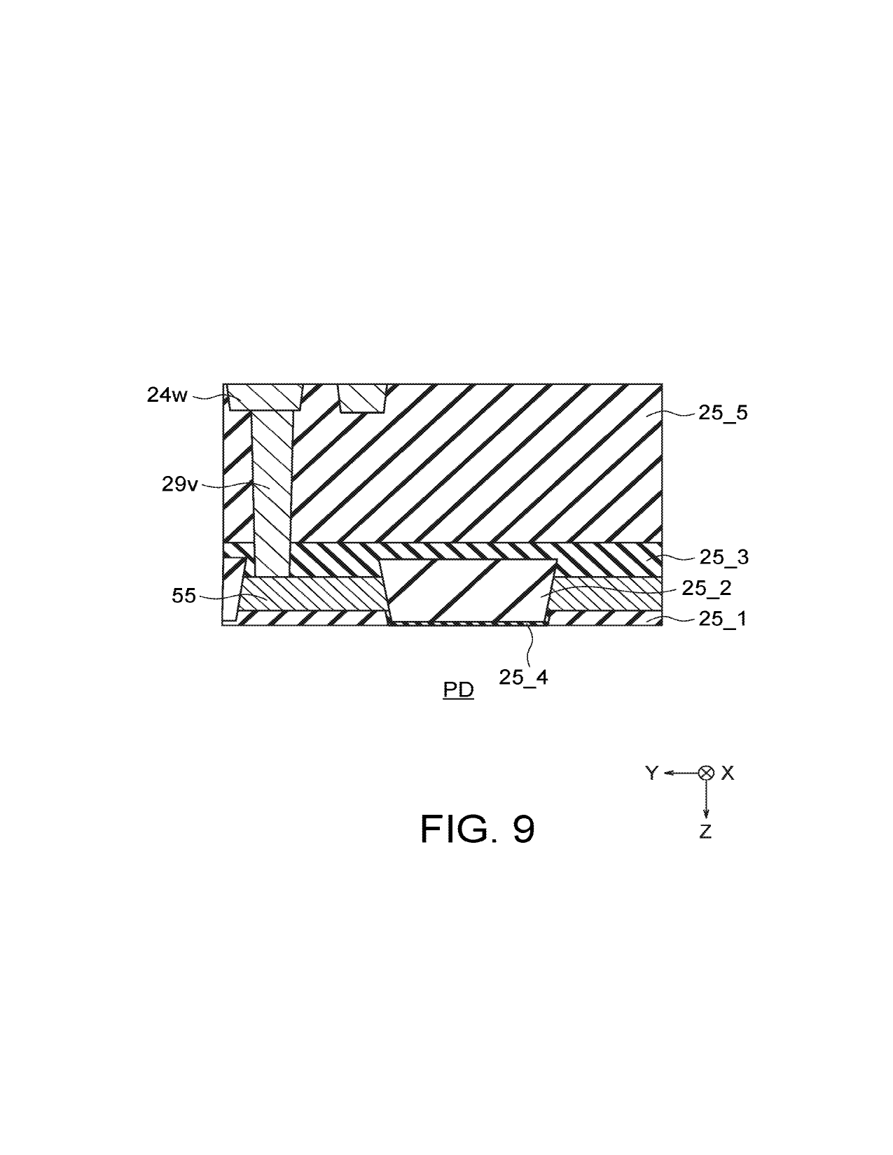

FIG. 9 is a sectional view illustrating a configuration example of the peripheral region PD. In the peripheral region PD, the inner part of the third insulating film 25_3 is filled with the material (for example, a silicon nitride film) of the third insulating film 25_3 and does not have air gaps AG. Lines 55 formed in the same layer as the bit lines BL are provided on the first insulating film 25_1. The second insulating film 25_2 is provided to penetrate through the lines 55. The inner part of the second insulating film 25_2 is also filled with the material (for example, a silicon dioxide film) of the second insulating film 25_2 and does not have air gaps AG. That is, a part between adjacent ones of the lines 55 is filled with the second insulating film 25_2 and air gaps AG are not provided therebetween. The fourth insulating film 25_4 is provided to connect ends of the lines 55 adjacent between the first insulating film 25_1 and the second insulating film 25_2. The fourth insulating film 25_4 in the peripheral region PD is formed at the same timing as that of the fourth insulating film 25_4 in the stacked body 20. The fourth insulating film 25_4 is formed by nitriding a part of the first insulating film 25_1 before providing the second insulating film 25_2 in the peripheral region PD. The third insulating film 25_3 is located on the lines 55 and the second insulating film 25_2. The fifth insulating film 25_5 is located on the third insulating film 25_3. Each of the via contacts 29v penetrates through the fifth insulating film 25_5 and the third insulating film 25_3 in the Z direction and electrically connects any of the lines 24w and a line 55.

In a data read operation, data in a selected memory cell of the memory cell array 2m in FIG. 1 is transmitted to the corresponding bit line BL through the semiconductor body 210 of the associated columnar body CL and the associated via contact 28vy. This data is further transmitted to the associated line 24w through the associated via contact 28v and is detected by a sense amplifier (not illustrated). In a data write operation, data from an external decoder is transmitted to a bit line BL through the associated line 24w and the associated via contact 28v. This data is transmitted to the semiconductor body 210 of the associated columnar body CL through the associated via contact 28vy and is written to a selected memory cell of the memory cell array 2m.

As described above, according to the present embodiment, the air gaps AG are provided between the bit lines BL in the air gap region Rag where the via contacts 28v are not formed. Therefore, the parasitic capacitances between the bit lines BL can be reduced. As a result, disturb of data between the bit lines BL can be suppressed. Furthermore, reliability of data can be maintained even when the bit lines BL are elongated.

Meanwhile, in the buried regions Rbr including the via formation region Rvia where the via contacts 28v are formed, the air gaps AG are not provided between the bit lines BL and the second insulating film 25_2 is buried therebetween. Accordingly, even when the positions of the via contacts 28v are slightly displaced as illustrated in FIG. 8, the second insulating film 25_2 suppresses each of the via contacts 28v from being connected to an unintended bit line BL.

If air gaps AG are provided between adjacent ones of the bit lines BL, the conductive material of the via contacts 28v may enter the air gaps AG to be connected to unintended bit lines BL when the positions of the via contacts 28v are displaced at the time of formation.

In contrast thereto, in the present embodiment, no air gap AG is provided between adjacent ones of the bit lines BL and the third insulating film 25_3 is buried therebetween in the buried regions Rbr. Therefore, the third insulating film 25_3 can suppress the via contacts 28v from electrically short-circuiting the bit lines BL or from being connected to unintended bit lines BL.

A manufacturing method of the semiconductor memory device 1 according to the present embodiment is described next.

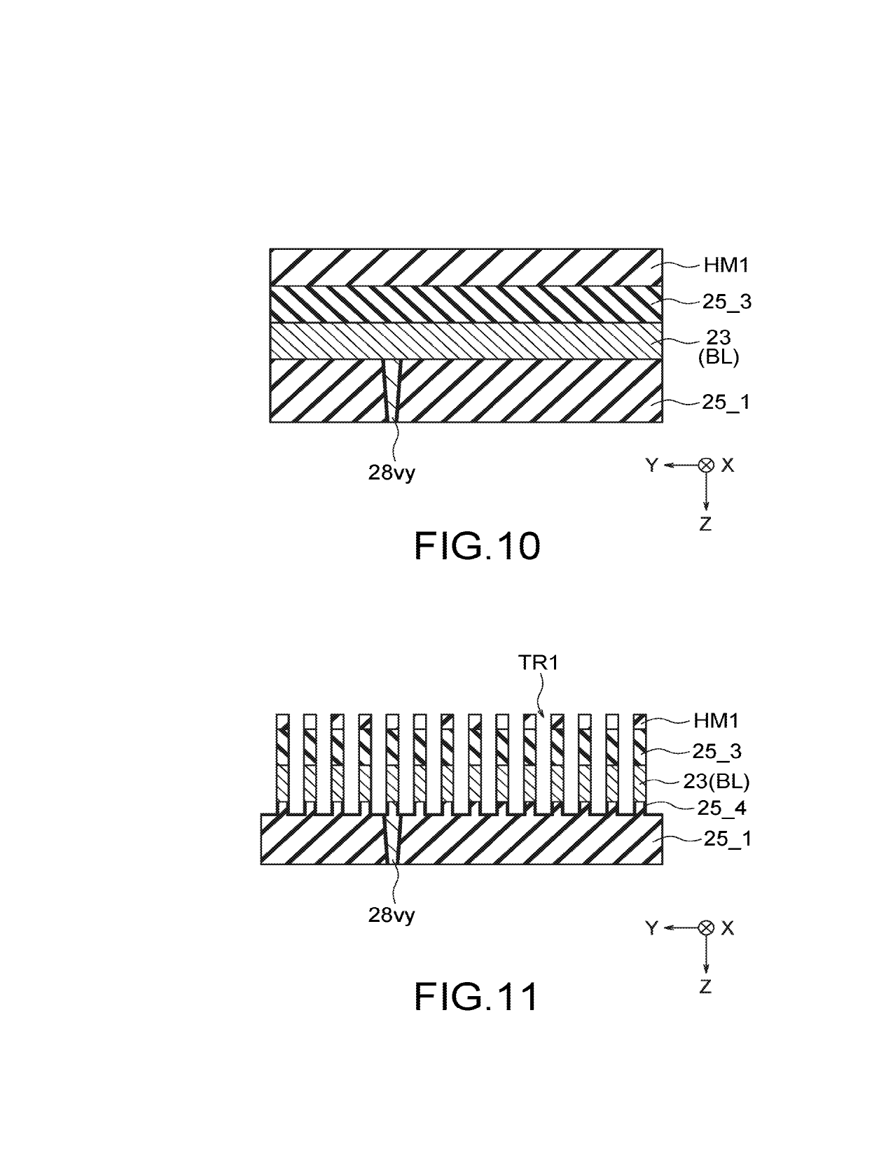

FIGS. 10 to 18 are sectional views illustrating one example of the manufacturing method of the semiconductor memory device 1 according to the first embodiment. The upward direction (the -Z direction) is one example of a first direction.

As illustrated in FIG. 10, the first insulating film 25_1 is deposited in the upward direction of the stacked body 20 (not illustrated) and the via contacts 28vy are formed in the first insulating film 25_1. Next, the material (for example, tungsten) of the bit lines BL is deposited on the first insulating film 25_1 and the via contacts 28vy. Next, the material (for example, a silicon nitride) of the third insulating film 25_3 is deposited on the material of the bit lines BL. Next, a material (for example, a silicon oxide) of a hard mask HM1 is deposited on the material of the third insulating film 25_3. A structure illustrated in FIG. 10 is thereby obtained.

Next, the material of the hard mask HM1 is processed into a layout pattern of the bit lines BL using a lithography technique and an etching technique. At that time, a mask pattern may be formed using sidewalls that are formed on both side surfaces of the pattern. Next, as illustrated in FIG. 11, the material of the third insulating film 25_3 and the material of the bit lines BL are etched by an etching technique such as an RIE (Reactive Ion Etching) method using the hard mask HM1 as a mask. Trenches TR1 between the bit lines BL are formed to penetrate through the third insulating film 25_3 and the bit lines BL to reach the first insulating film 25_1. The first insulating film 25_1 is exposed on bottoms of the trenches TR1. The bit lines BL are thereby formed. The bit lines BL and the third insulating film 25_3 located thereon extend in the X direction and are arrayed in the Y direction. The third insulating film 25_3 is provided in the -Z direction of the bit lines BL to be associated with each of the bit lines BL.

Next, the surface of the first insulating film 25_1 exposed on the bottoms of the trenches TR1 is nitrided by nitriding processing to form the fourth insulating film 25_4. The fourth insulating film 25_4 is formed, for example, by performing plasma processing to the surface of the first insulating film 25_1 to reform the surface of the first insulating film 25_1. The fourth insulating film 25_4 functions as an etching stopper at the time of removing the second insulating film 25_2 later.

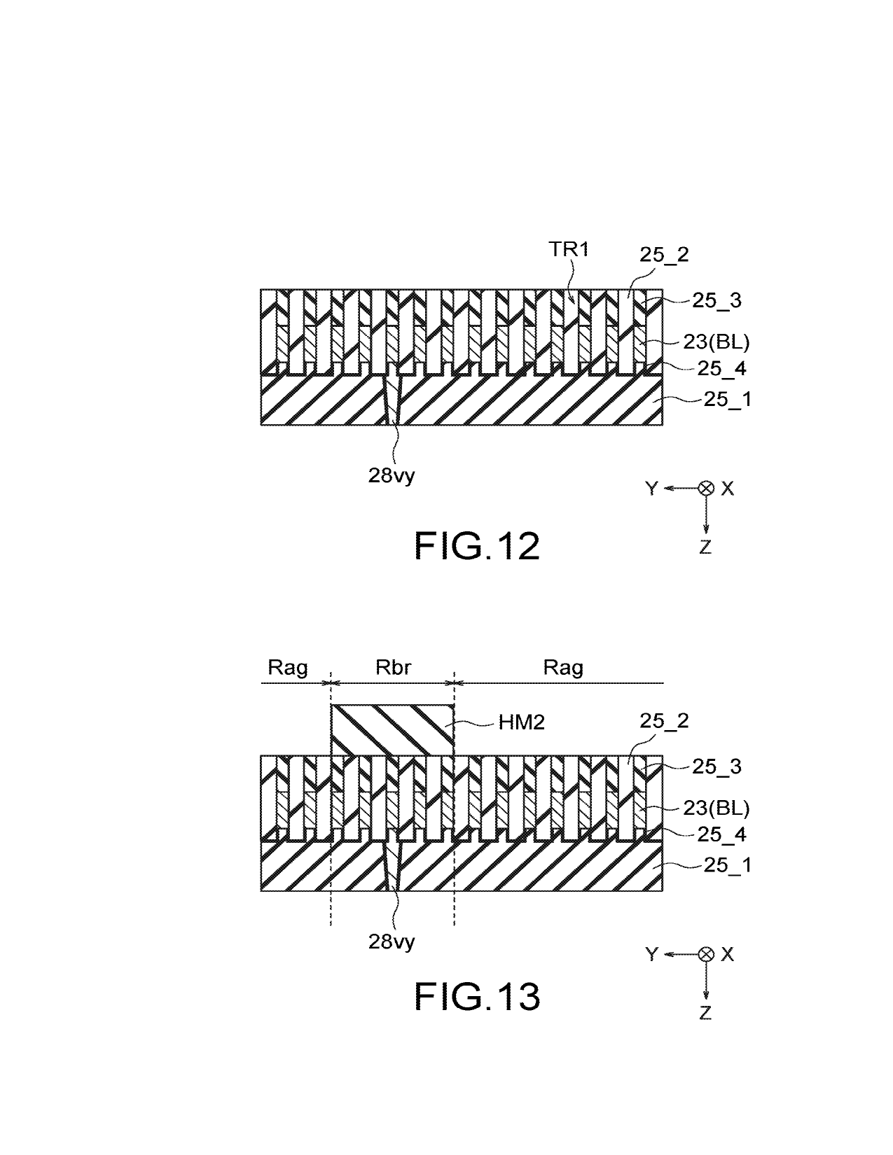

Next, the material (for example, a silicon oxide) of the second insulating film 25_2 is deposited in the trenches TR1 and on the hard mask HM1. The second insulating film 25_2 and the hard mask HM1 are polished by a CMP (Chemical Mechanical Polishing) method until the upper surface of the third insulating film 25_3 is exposed. The trenches TR1 between the bit lines BL are thereby filled with the second insulating film 25_2 as illustrated in FIG. 12. At that time, the air gaps AG are not provided in the second insulating film 25_2.

Next, a material of a hard mask HM2 is deposited on the second and third insulating films 25_2 and 25_3. The material of the hard mask HM2 is a material that can be selectively etched with respect to the second and third insulating films 25_2 and 25_3.

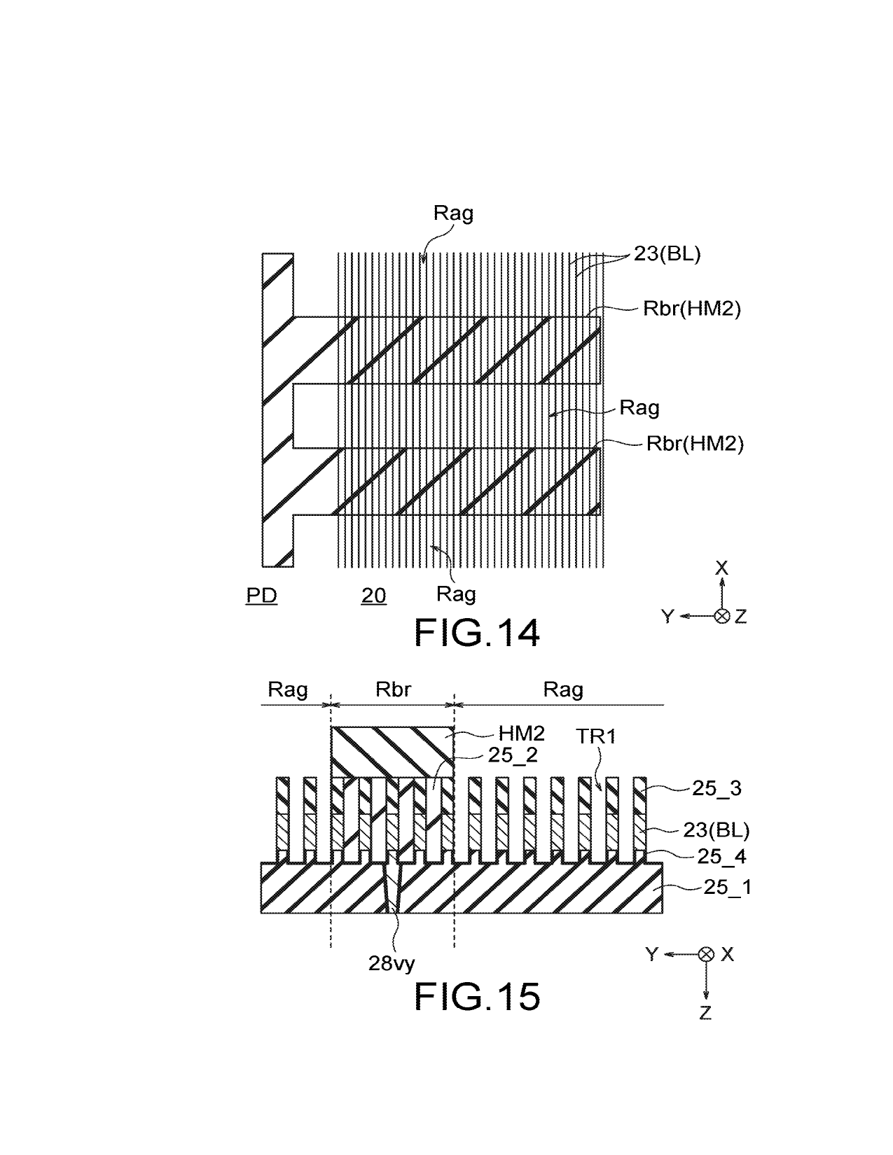

Next, the material of the hard mask HM2 in the air gap region Rag is removed by a lithography technique and an etching technique to leave the hard mask HM2 in the buried region Rbr as illustrated in FIG. 13. At that time, in a planar view viewed from the Z direction, the hard mask HM2 is left on the buried region Rbr as illustrated in FIG. 14.

Next, as illustrated in FIG. 15, the second insulating film 25_2 in the trenches TR1 in the air gap region Rag is selectively etched using the hard mask HM2 as a mask. The second insulating film 25_2 in the trenches TR1 in the buried region Rbr is left. That is, as viewed from the Z direction, the second insulating film 25_2 in the air gap region Rag other than the buried region Rbr is selectively removed and the trenches TR1 are formed between the bit lines BL in the air gap region Rag.

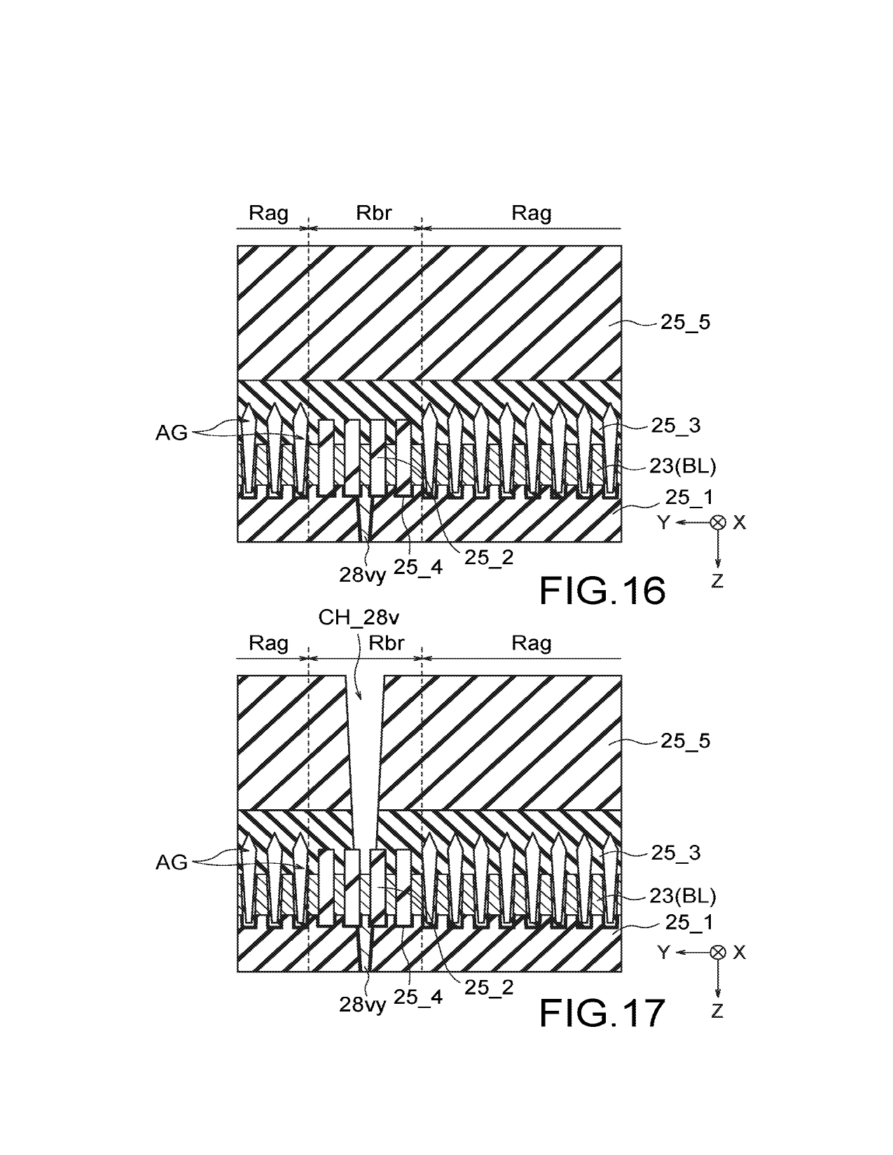

Next, after the hard mask HM2 is removed, the material (for example, a silicon nitride) of the third insulating film 25_3 is further deposited on the second insulating film 25_2 and the third insulating film 25_3 from the -Z direction as illustrated in FIG. 16. At that time, the material of the third insulating film 25_3 is deposited by a plasma CVD (Chemical Vapor Deposition) method or the like on a condition where step coverage is decreased. Accordingly, in the air gap region Rag, the material of the third insulating film 25_3 closes openings of the trenches TR1 and leaves an air gap AG in each thereof. The material of the third insulating film 25_3 is thinly formed on inner walls and bottom surfaces of the trenches TR1. Since the fourth insulating film 25_4 has been formed on the bottoms of the trenches TR1 in the air gap region Rag, the third insulating film 25_3 in the air gap region Rag is formed on the fourth insulating film 25_4. Therefore, the third insulating film 25_3 is located between each of the bit lines BL and adjacent air gaps AG and between the first insulating film 25_1 and the air gaps AG. Meanwhile, since the second insulating film 25_2 is buried in the trenches TR1 in the buried region Rbr, no air gaps AG are left in the third insulating film 25_3.

Next, the material (for example, a silicon oxide) of the fifth insulating film 25_5 is deposited on the third insulating film 25_3. A structure illustrated in FIG. 16 is thereby obtained.

Next, contact holes CH_28v are formed at positions of the via contacts 28v using a lithography technique and an etching technique as illustrated in FIG. 17. The contact holes CH_28v are formed in the via formation region Rvia in the buried region Rbr. The contact holes CH_28v penetrate through the fifth insulating film 25_5 and the third insulating film 25_3 to reach the corresponding bit lines BL, respectively. At that time, in the buried region Rbr, no air gap AG is formed between the bit lines BL and a part between the bit lines BL is filled with the second insulating film 25_2. Therefore, even when the contact holes CH_28v are displaced in the Y direction by the width of the second insulating film 25_2, the contact holes CH_28v do not reach adjacent other bit lines BL. That is, by filling a part between the bit lines BL with the second insulating film 25_2, a margin of the width of the second insulating film 25_2 is provided for misalignment of the contact holes CH_28v.

Meanwhile, in the air gap region Rag, the air gaps AG are formed between the bit lines BL. Therefore, the parasitic capacitances between the bit lines BL can be reduced. Accordingly, disturb between the bit lines BL can be suppressed.

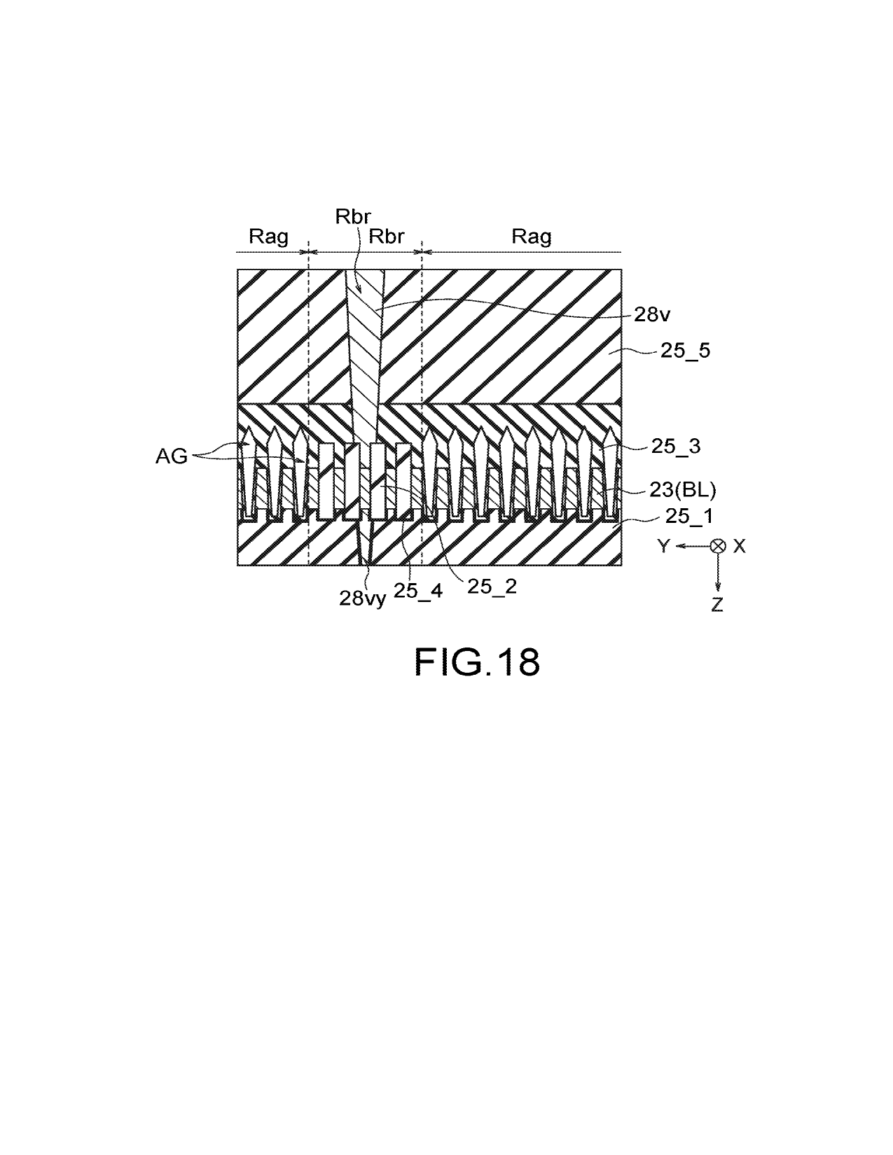

Next, as illustrated in FIG. 18, the material (for example, tungsten) of the via contacts 28v is embedded in the contact holes CH_28v. At that time, after the material of the via contacts 28v is deposited on the fifth insulating film 25_5 and in the contact holes CH_28v, the material of the via contacts 28v is polished by the CMP method or the like until the fifth insulating film 25_5 is exposed. Accordingly, the contact holes CH_28v are filled with the via contacts 28v, respectively.

Subsequently, the lines 24w and the like are formed as illustrated in FIG. 8 and the array chip 2 is completed.

The CMOS chip 3 formed separately from the array chip 2 is bonded to the array chip 2. The semiconductor memory device 1 according to the first embodiment is thereby completed as illustrated in FIG. 1.

According to the present embodiment, the air gaps AG are provided between the bit lines BL in the air gap region Rag. Therefore, the parasitic capacitances between the bit lines BL can be reduced. Accordingly, disturb of data between the bit lines BL can be suppressed to improve the reliability of the semiconductor memory device 1. Furthermore, the bit lines BL can be further elongated in the X direction while the parasitic capacitances between the bit lines BL are maintained.

Meanwhile, in the buried region Rbr, a part between adjacent ones of the bit lines BL is filled with the second insulating film 25_2. Therefore, even when the via contacts 28v are displaced in the Y direction by the width of the second insulating film 25_2, the via contacts 28v are not in contact with adjacent other bit lines BL. That is, by filling a part between adjacent ones of the bit lines BL with the second insulating film 25_2, a certain margin is provided for misalignment of the via contacts 28v.

### Second embodiment

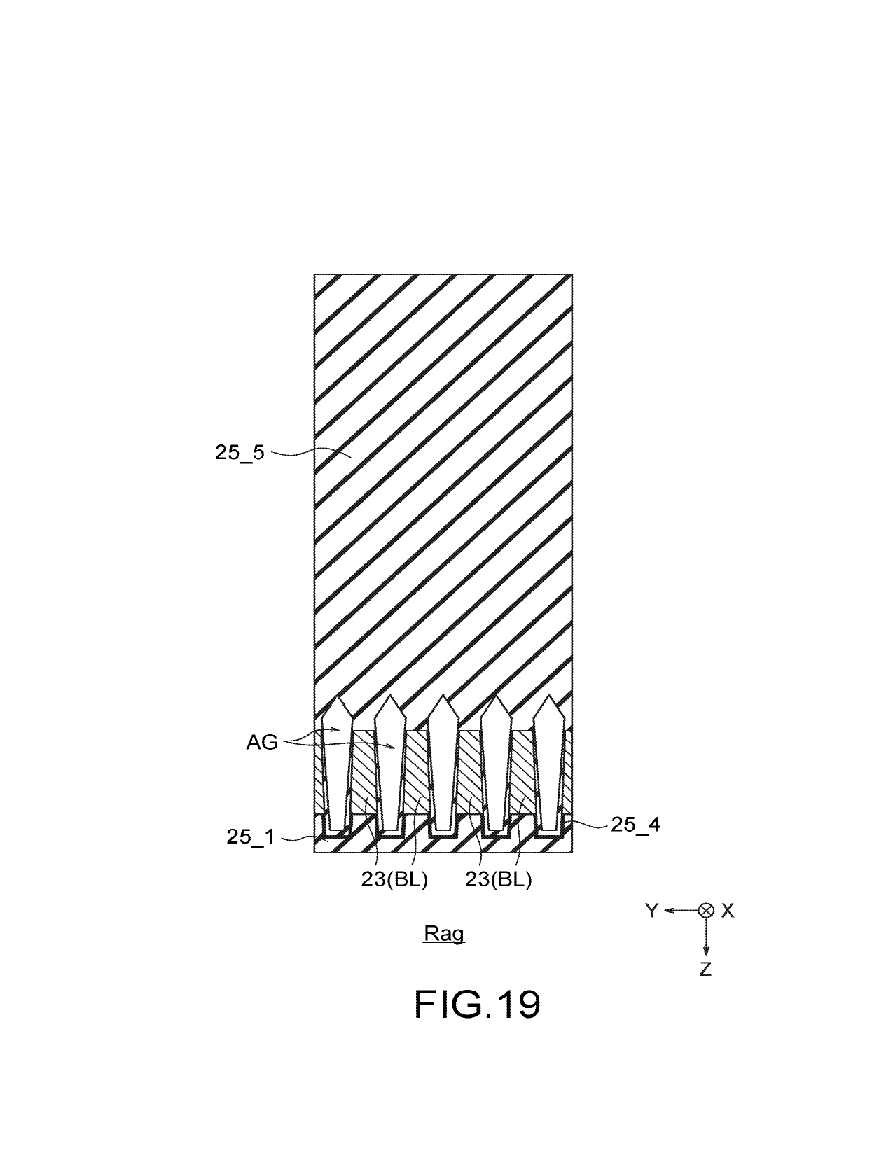

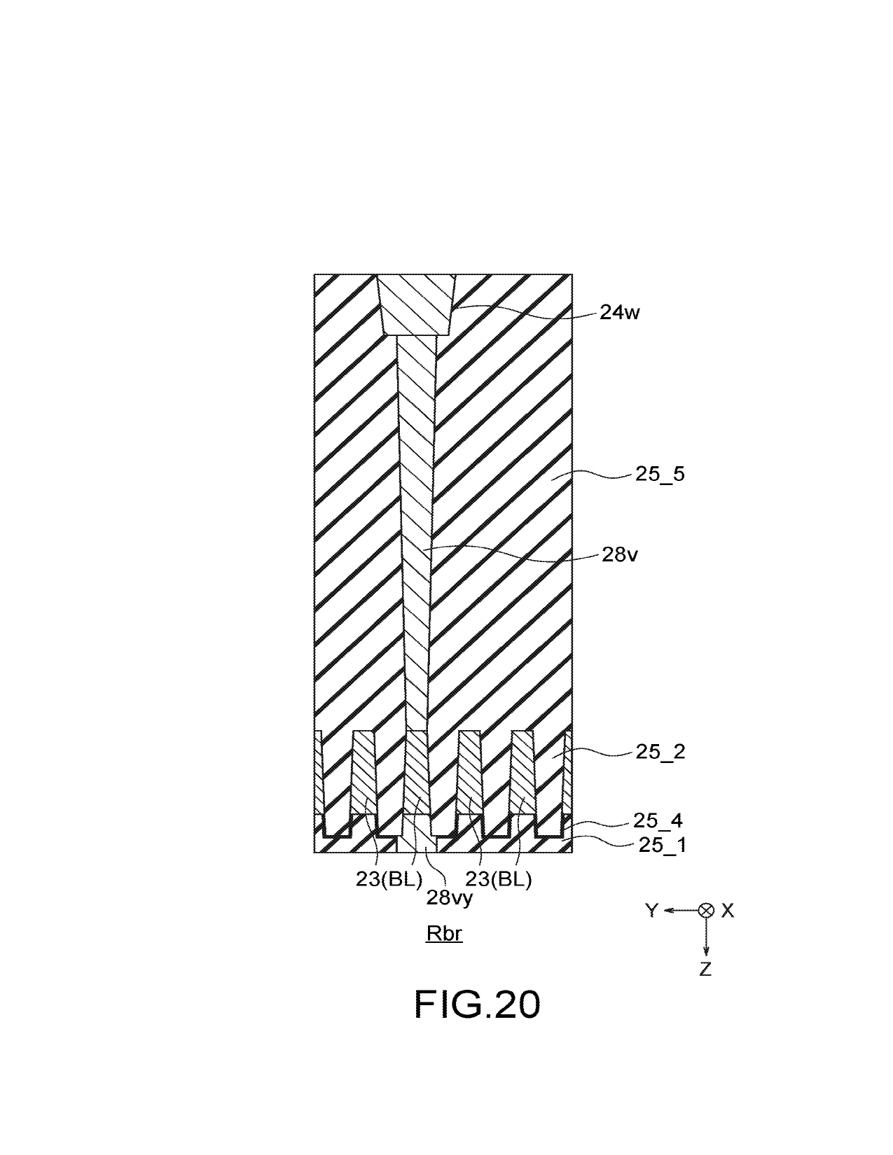

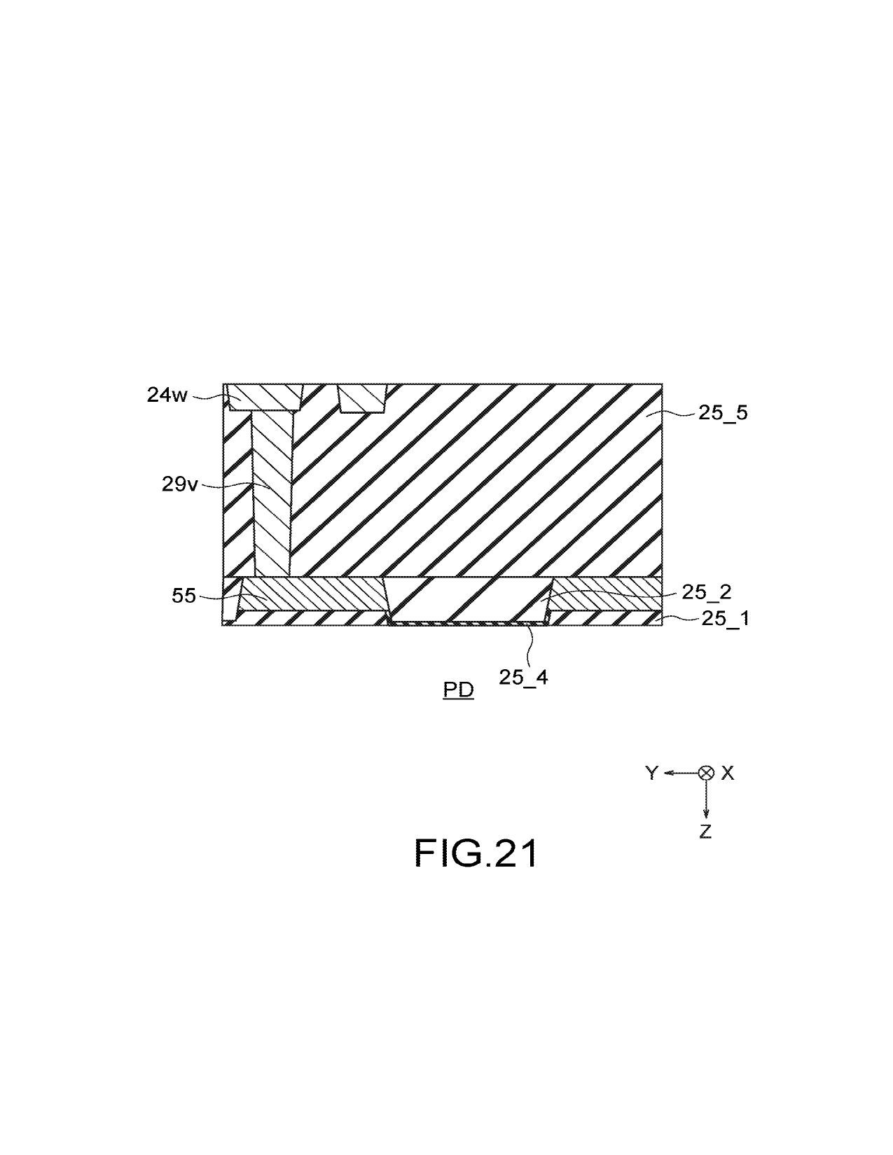

FIGS. 19 and 20 are sectional views illustrating a configuration example of the bit lines BL and a part peripheral thereto in the air gap region Rag of a semiconductor memory device according to a second embodiment. FIG. 19 corresponds to the cross section along the line 7-7 in FIG. 5. FIG. 20 corresponds to the cross section along the line 8-8 in FIG. 5. FIG. 21 is a sectional view illustrating a configuration example of the peripheral region PD of the semiconductor memory device according to the second embodiment.

In the second embodiment, the third insulating film 25_3 is not provided, and the fifth insulating film 25_5 functions as an air gap insulating film to coat the bit lines BL, the second insulating film 25_2, and the air gaps AG.

The fifth insulating film 25_5 as the air gap insulating film is located on the bit lines BL in the air gap region Rag. The fifth insulating film 25_5 is also located around the air gaps AG and encompasses the air gaps AG. That is, the fifth insulating film 25_5 is located between the bit lines BL and internally has the air gaps AG. The fifth insulating film 25_5 is located on the bit lines BL and the second insulating film 25_2 in the buried region Rbr. For example, an insulating material such as a silicon oxide is used as the fifth insulating film 25_5. The fifth insulating film 25_5 is also referred to as the third insulating film.

The fifth insulating film 25_5 is provided on the sidewalls of the bit lines BL. Therefore, the fifth insulating film 25_5 is located between the sidewalls of the bit lines BL and the air gaps AG. The fifth insulating film 25_5 is also located between the side and bottom surfaces of the first insulating film 25_1 and the air gaps AG. That is, the air gaps AG are surrounded by the fifth insulating film 25_5. This enables the parasitic capacitances between the bit lines BL to be effectively reduced.

The rest of the configuration in the second embodiment may be identical to that in the first embodiment. Accordingly, the second embodiment can obtain the same effects as those in the first embodiment.

A manufacturing method of the semiconductor memory device 1 according to the second embodiment is described next.

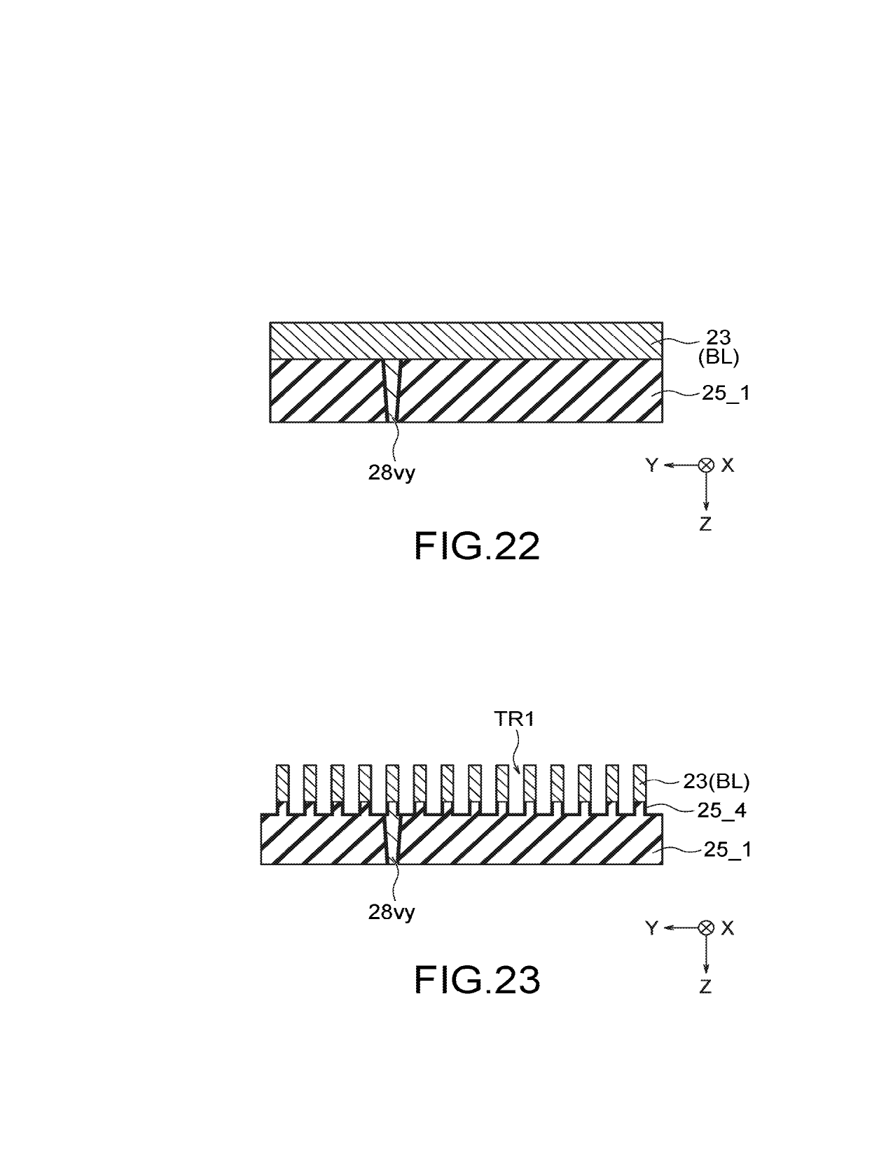

FIGS. 22 to 29 are sectional views illustrating one example of the manufacturing method of the semiconductor memory device 1 according to the second embodiment.

Formation processes of the first insulating film 25_1, the via contacts 28vy, and the material of the bit lines BL illustrated in FIG. 22 may be the same as the formation processes of those in the first embodiment.

Next, the material of the bit lines BL is etched using a hard mask, a lithography technique, and an etching technique. The trenches TR1 between the bit lines BL are formed to penetrate through the bit lines BL to reach the first insulating film 25_1. The first insulating film 25_1 is exposed on bottoms of the trenches TR1. The bit lines BL are thereby formed. The bit lines BL extend in the X direction and are arrayed in the Y direction.

Next, the surface of the first insulating film 25_1 exposed on the bottoms of the trenches TR1 is nitrided by nitriding processing to form the fourth insulating film 25_4. The fourth insulating film 25_4 functions as an etching stopper at the time of removing the second insulating film 25_2 later.

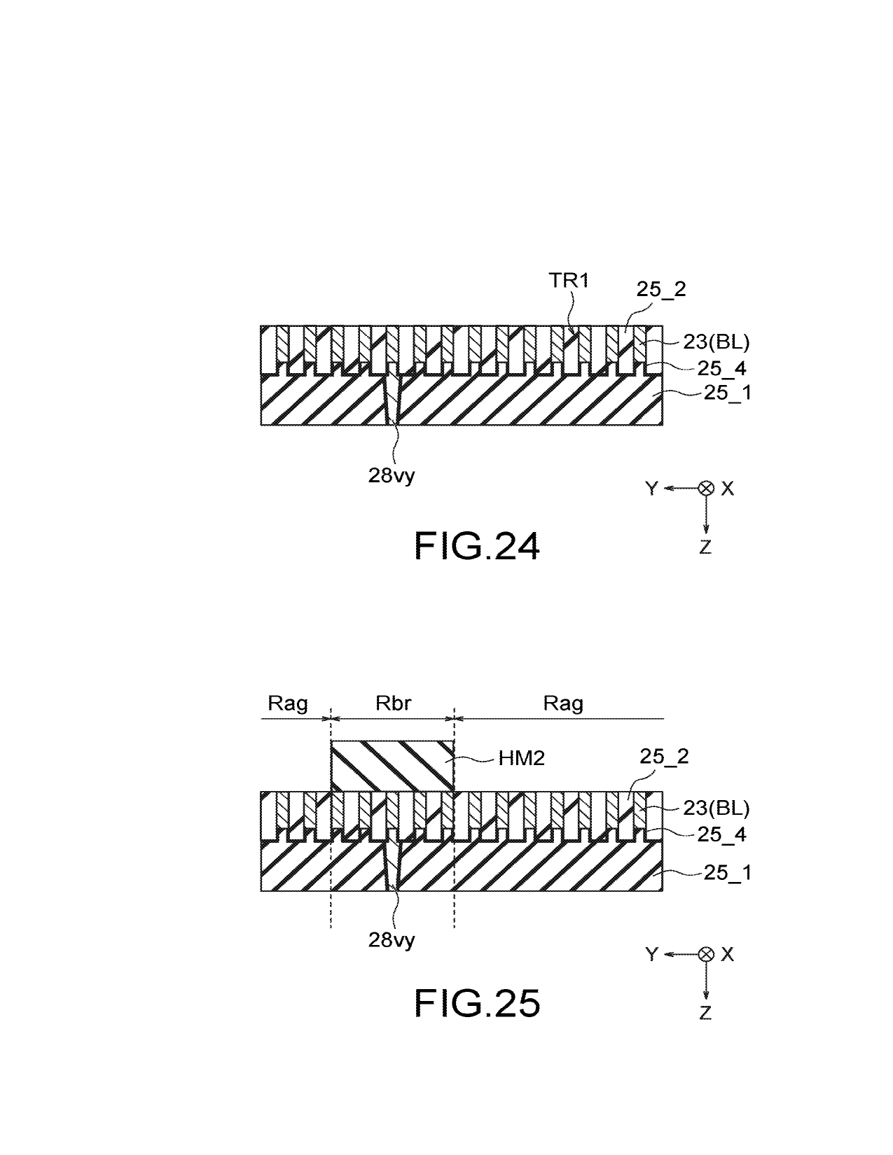

Next, the material (for example, a silicon oxide) of the second insulating film 25_2 is deposited in the trenches TR1. The second insulating film 25_2 is polished using the CMP method until the upper surfaces of the second insulating film 25_2 and the bit lines BL are exposed. The trenches TR1 between the bit lines BL are thereby filled with the second insulating film 25_2 as illustrated in FIG. 24. At that time, no air gaps AG are provided in the second insulating film 25_2.

Next, the material of the hard mask HM2 is deposited on the second insulating film 25_2 and the bit lines BL.

Next, the material of the hard mask HM2 in the air gap region Rag is removed by a lithography technique and an etching technique to leave the hard mask HM2 in the buried region Rbr as illustrated in FIG. 25.

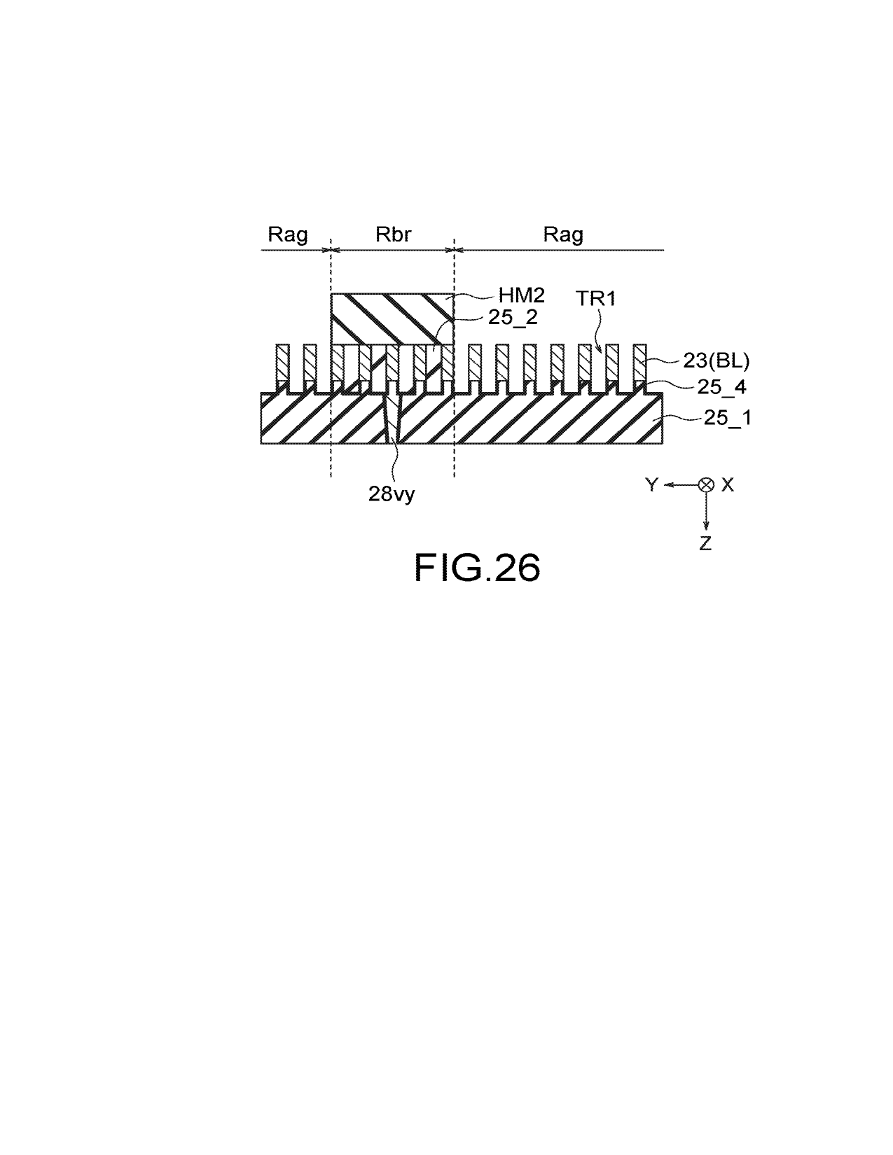

Next, as illustrated in FIG. 26, the second insulating film 25_2 in the trenches TR1 in the air gap region Rag is selectively etched using the hard mask HM2 as a mask. The second insulating film 25_2 in the trenches TR1 in the buried region Rbr is left.

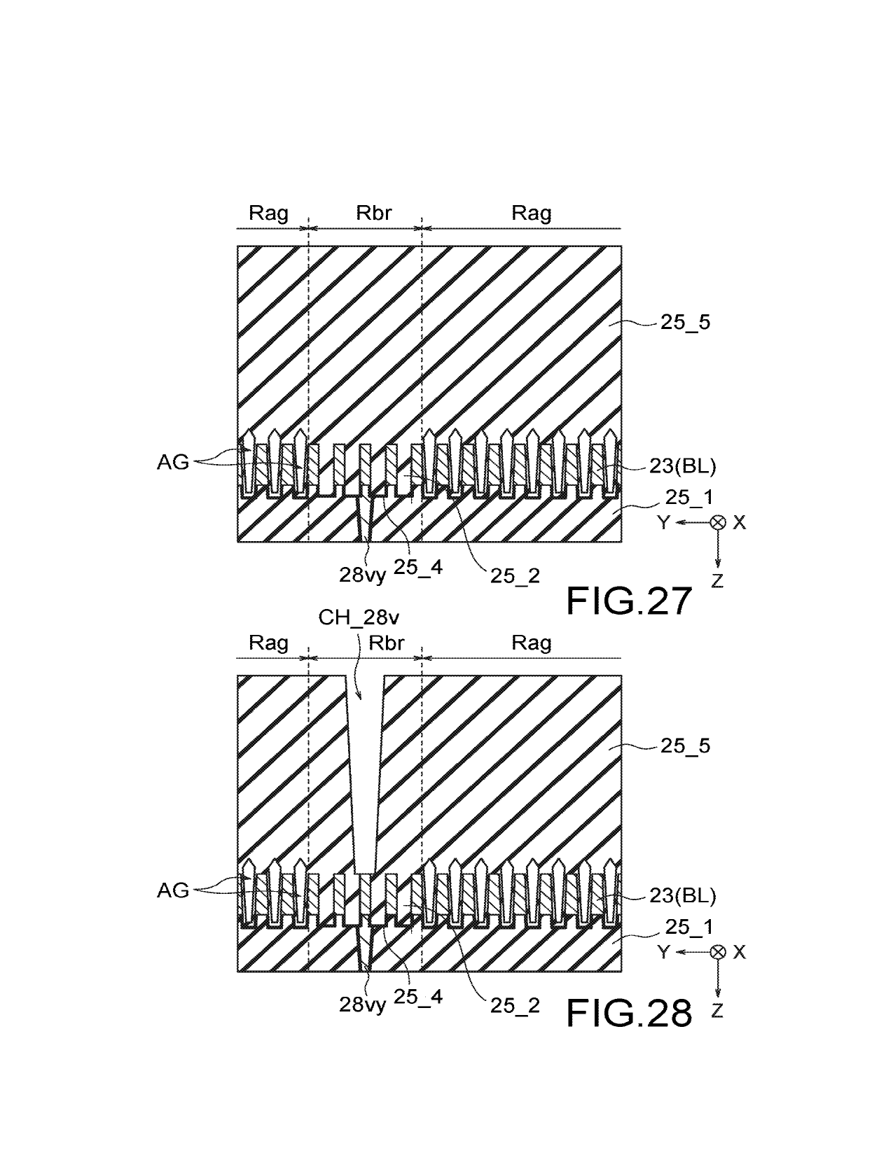

Next, after the hard mask HM2 is removed, the material of the fifth insulating film 25_5 is further deposited on the second insulating film 25_2 and the bit lines BL from the -Z direction as illustrated in FIG. 27. At that time, the material of the fifth insulating film 25_5 is deposited by the CVD method or the like on a condition where step coverage is decreased. Accordingly, in the air gap region Rag, the material of the fifth insulating film 25_5 closes openings of the trenches TR1 to leave an air gap AG in each thereof. The material of the fifth insulating film 25_5 is thinly formed on the inner walls and the bottom surfaces of the trenches TR1. Therefore, the fifth insulating film 25_5 is located between each of the bit lines BL and adjacent air gaps AG and between the first insulating film 25_1 and the air gaps AG. Meanwhile, since the second insulating film 25_2 is buried in the trenches TR1 in the buried region Rbr, no air gaps AG are left in the fifth insulating film 25_5.

Next, the contact holes CH_28v are formed at positions of the via contacts 28v using a lithography technique and an etching technique as illustrated in FIG. 28. The contact holes CH_28v are formed in the via formation region Rvia in the buried region Rbr. The contact holes CH_28v penetrate through the fifth insulating film 25_5 to reach the corresponding bit lines BL, respectively. At that time, in the buried region Rbr, no air gap AG is formed between the bit lines BL and a part between the bit lines BL is filled with the second insulating film 25_2. Therefore, even when the contact holes CH_28v are displaced in the Y direction by the width of the second insulating film 25_2, the contact holes CH_28v do not reach adjacent other bit lines BL. That is, by filling a part between the bit lines BL with the second insulating film 25_2, a margin of the width of the second insulating film 25_2 is provided for misalignment of the contact holes CH_28v.

Meanwhile, in the air gap region Rag, the air gaps AG are formed between the bit lines BL. Therefore, the parasitic capacitances between the bit lines BL can be reduced. Accordingly, disturb of data between the bit lines BL can be suppressed.

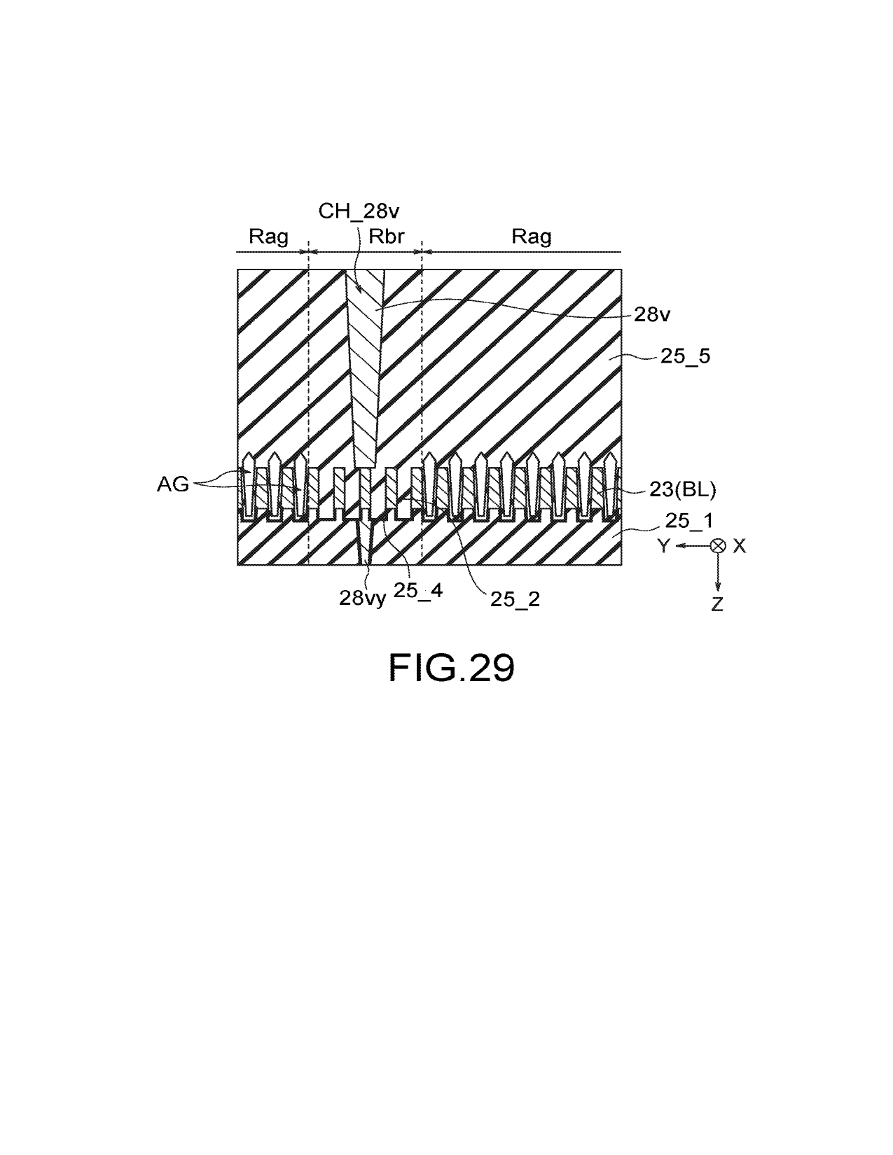

Next, as illustrated in FIG. 29, the material (for example, tungsten) of the via contacts 28v is embedded in the contact holes CH_28v.

Subsequently, the lines 24w and the like are formed and the array chip 2 is completed.

The CMOS chip 3 formed separately from the array chip 2 is bonded to the array chip 2. The semiconductor memory device 1 illustrated in FIG. 1 is thereby completed.

Although the third insulating film 25_3 is omitted in the second embodiment, the rest of the configuration in the second embodiment is substantially identical to that in the first embodiment. Accordingly, the second embodiment can obtain the same effects as those in the first embodiment.

### Third embodiment

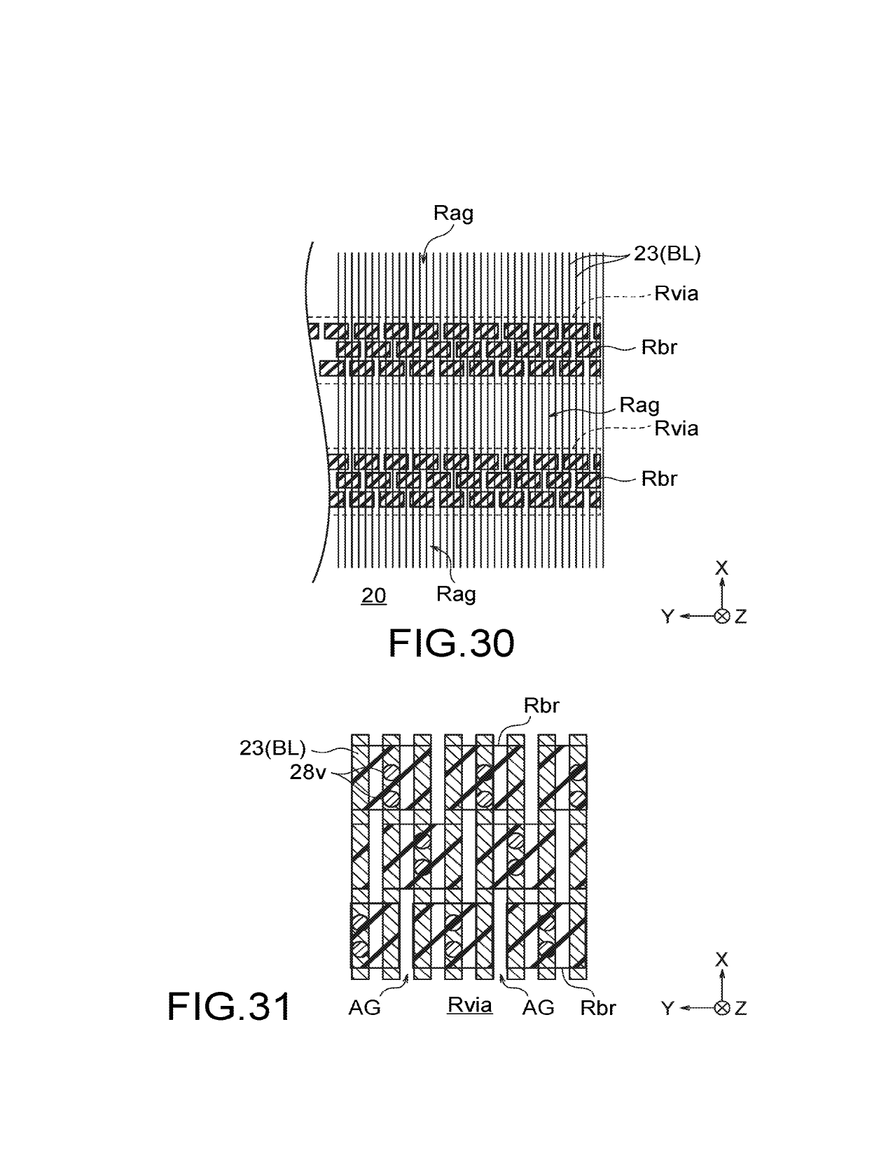

FIG. 30 is a plan view illustrating a configuration example of a semiconductor memory device according to a third embodiment. FIG. 30 illustrates a plan view of a part of the stacked body 20. FIG. 31 is a plan view illustrating more details of a portion of FIG. 30. The peripheral region PD may be identical to that of the first embodiment.

In the third embodiment, as viewed from the Z direction, a buried region Rbr is provided to be associated with one or a plurality of via contacts 28v connected to each bit line BL and is provided in an island manner to be associated with each bit line BL.

For example, as illustrated in FIG. 31, two via contacts 28v are connected to each bit line BL. In this case, each buried region Rbr is provided to be associated with two via contacts 28v and is provided for the two via contacts 28v and a peripheral part thereto as viewed from the Z direction. That is, a plurality of buried regions Rbr in the island manner are provided in the via formation region Rvia. One of the buried regions Rbr in the island manner includes a part of one of the bit lines BL and a part of bit lines adjacent to this bit line BL around via contacts 28v connected to this bit line BL as viewed from the Z direction.

A part between the bit lines BL in the buried regions Rbr is filled with the second insulating film 25_2 similarly in the first embodiment. However, in the third embodiment, each of the buried regions Rbr is provided in the island manner in the via formation region Rvia and the air gap AG is provided between the bit lines BL between adjacent ones of the buried regions Rbr. That is, the air gaps AG are formed also in a part of the via formation region Rvia. Accordingly, the capacitances between the bit lines BL are further reduced.

It is preferable that the buried regions Rbr are arranged substantially uniformly in the via formation region Rvia. This enables the capacitances between bit lines BL to be substantially equal without varying.

The air gaps AG are provided between the bit lines BL in the air gap region Rag similarly in the first embodiment. As described above, while the planar layout of the buried regions Rbr and the air gap region Rag in the third embodiment is different from that in the first embodiment, the rest of the configuration in the third embodiment may be identical to that in the first embodiment. Accordingly, the third embodiment can also obtain the same effects as those in the first embodiment. The third embodiment may be combined with the second embodiment.

### Fourth embodiment

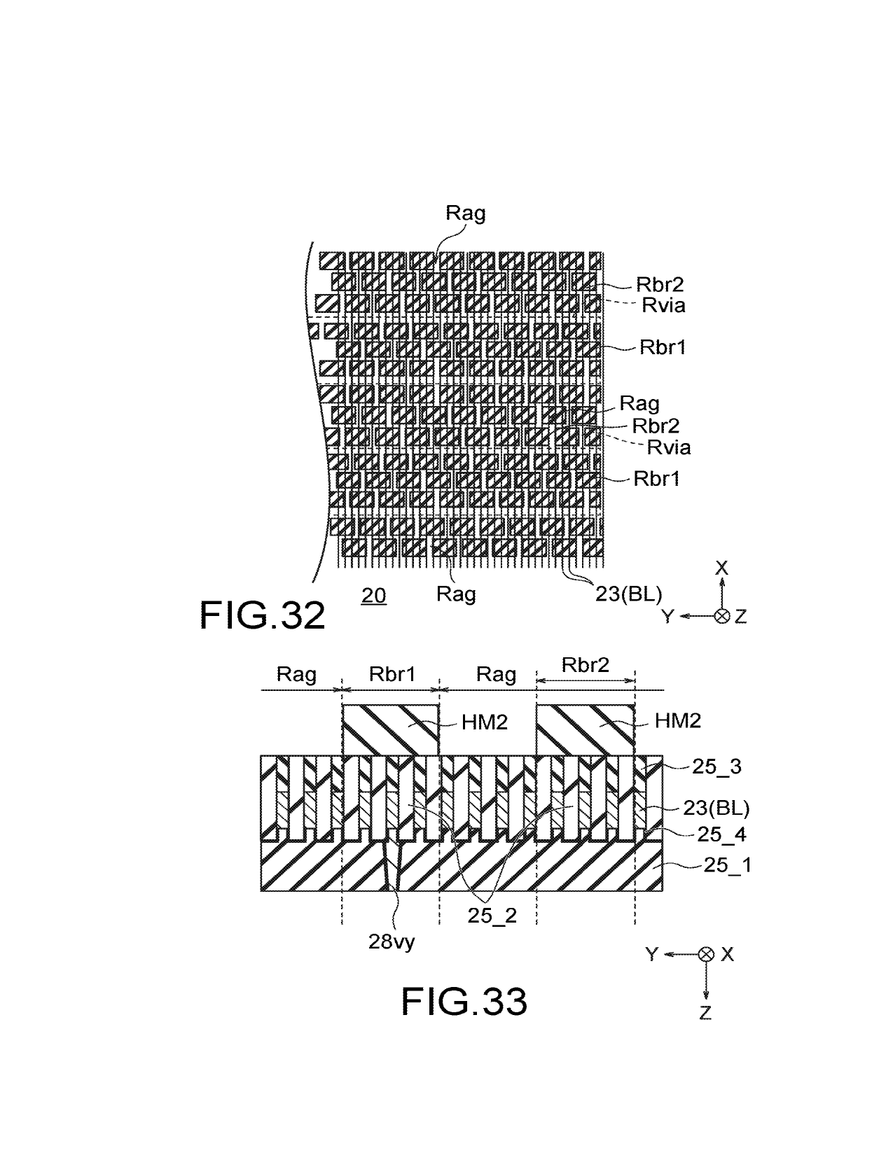

FIG. 32 is a plan view illustrating a configuration example of a semiconductor memory device according to a fourth embodiment. FIG. 32 illustrates a plan view of a part of the stacked body 20. A more detailed plan view of the via formation region Rvia may be the same as that of FIG. 31. The peripheral region PD may be the same as that of the first embodiment.

In the fourth embodiment, as viewed from the Z direction, a buried region Rbr is provided to be associated with one or a plurality of via contacts 28v connected to each bit line BL and is provided in an island manner to be associated with each bit line BL. The fourth embodiment is the same as the third embodiment in this point. Buried regions Rbr provided in the via formation region Rvia are referred to as buried regions Rbr1 for the sake of descriptions.

In the fourth embodiment, a plurality of buried regions Rbr2 are further provided in a part of the air gap region Rag. While the buried regions Rbr2 as third regions are regions where a part between the bit lines BL is filled with the second insulating film 25_2 similarly to the buried regions Rbr1, the buried regions Rbr2 are different from the buried regions Rbr1 in being provided in the air gap region Rag. The via contacts 28v are not formed in the buried regions Rbr2. Therefore, the contact holes CH_28v are not formed either in the buried regions Rbr2 in the manufacturing process.

For example, as illustrated in FIG. 32, each of the buried regions Rbr2 is provided in the island manner in the air gap region Rag to be associated with one or a plurality of bit lines BL as viewed from the Z direction. The planar layout of the buried regions Rbr2 can be the same as that of the buried regions Rbr1.

According to the fourth embodiment, the buried regions Rbr2 are provided in the air gap region Rag. Accordingly, in the CMP process in the process of forming the via contacts 28v and the like, the buried regions Rbr2 can support the third and fifth insulating films 25_3 and 25_5 to suppress the air gap region Rag from sagging or cracking.

The buried regions Rbr2 are provided in a part of the air gap region Rag and the air gaps AG are provided in the rest of the air gap region Rag. Therefore, the effect of reducing the parasitic capacitances between bit lines BL is also obtained.

A manufacturing method of the semiconductor memory device 1 according to the fourth embodiment is described next.

FIGS. 33 to 35 are sectional views illustrating one example of the manufacturing method of the semiconductor memory device according to the fourth embodiment. After the processes described with reference to FIGS. 10 to 12 are performed, the material of the hard mask HM2 is deposited on the second and third insulating films 25_2 and 25_3.

Next, the material of the hard mask HM2 located in a region other than the buried regions Rbr2 in the air gap region Rag is removed using a lithograph technique and an etching technique to leave the hard mask HM2 in the buried regions Rbr1 and Rbr2 as illustrated in FIG. 33. At that time, the mask pattern in the lithography process is different from that in the first embodiment.

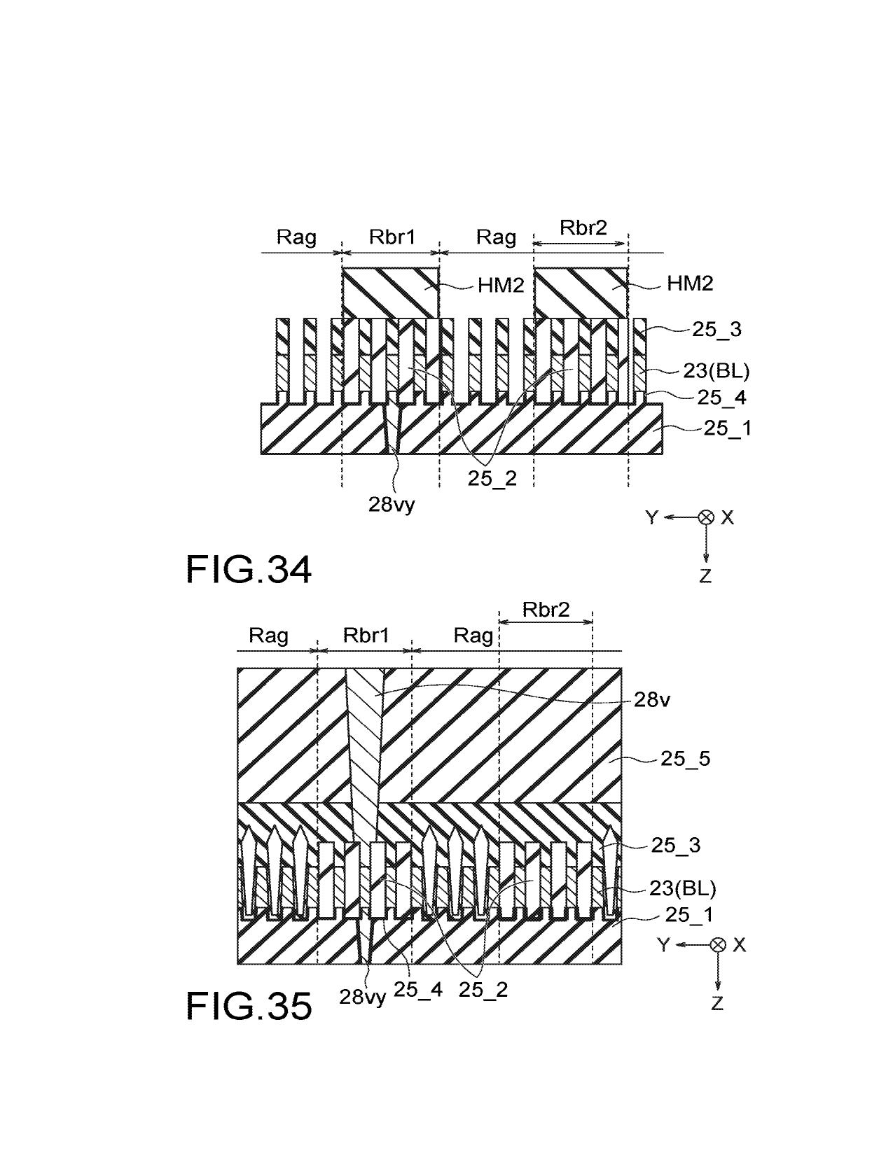

Next, as illustrated in FIG. 34, the second insulating film 25_2 in the trenches TR1 in a region other than the buried regions Rbr1 and the buried regions Rbr2 is selectively etched using the hard mask HM2 as a mask. The second insulating film 25_2 in the trenches TR1 in the buried regions Rbr1 and Rbr2 is left. That is, the second insulating film 25_2 in the region other than the buried regions Rbr1 and Rbr2 is selectively removed and the trenches TR1 are formed between adjacent ones of the bit lines BL, respectively, in the air gap region Rag as viewed from the Z direction.

Subsequently, the processes described with reference to FIGS. 15 to 18 are performed and a structure illustrated in FIG. 35 is obtained. At that time, while the via contacts 28v are formed in the buried regions Rbr1, the contact holes CH_28v and the via contacts 28v are not formed and the third and fifth insulating films 25_3 and 25_5 are provided on the bit lines BL in the buried regions Rbr2.

Subsequently, the processes identical to those of the first embodiment are performed and the semiconductor memory device according to the fourth embodiment is completed.

According to the fourth embodiment, the buried regions Rbr2 are provided in the air gap region Rag. Accordingly, in the CMP process in the process of forming the via contacts 28v and the like, the buried regions Rbr2 can support the third and fifth insulating films 25_3 and 25_5 to suppress the air gap region Rag from sagging or cracking.

It is preferable that the buried regions Rbr1 and Rbr2 are arranged substantially uniformly in the formation region of the bit lines BL. This causes the mechanical strength to be substantially uniform and further suppresses cracking in the CMP process. Furthermore, the capacitances between the bit lines BL do not vary according to places and become substantially uniform.

The rest of the configuration in the fourth embodiment may be identical to that in the first embodiment. Accordingly, the fourth embodiment can obtain the same effects as those in the first embodiment. The fourth embodiment may be combined with the second embodiment. The planar layout of the buried regions Rbr1 in the fourth embodiment may be the same as that in the first embodiment or the second embodiment. That is, the planar layout of the buried regions Rbr1 in the fourth embodiment may be in the form of stripes.

### Modifications

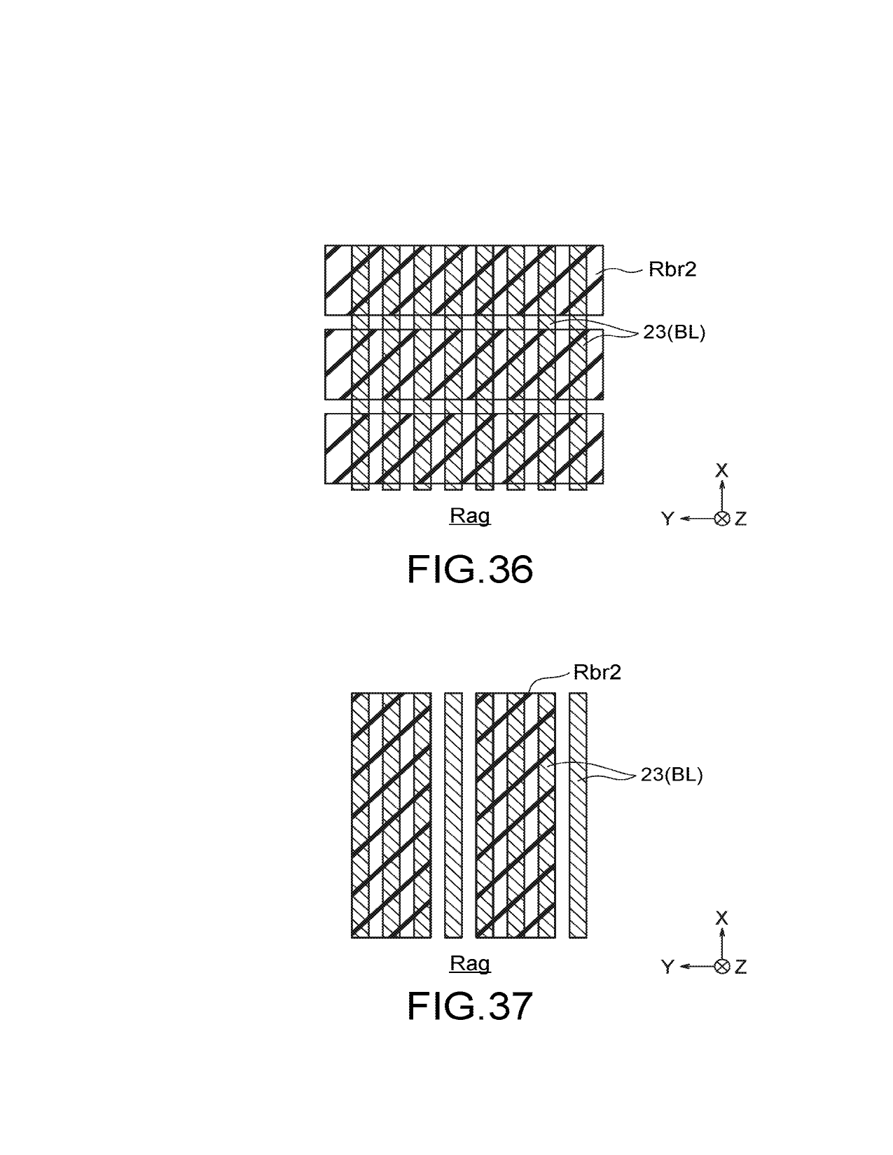

FIGS. 36 to 39 are sectional views illustrating configuration examples of a semiconductor memory device according to modifications of the fourth embodiment. In these modifications, the layouts of the buried regions Rbr2 in the air gap region Rag viewed from the Z direction are different. The rest of the configurations in the modifications may be identical to that in the fourth embodiment.

In FIG. 36, the buried regions Rbr2 have a layout in the form of stripes extending in the Y direction and arrayed in the X direction.

In FIG. 37, the buried regions Rbr2 have a layout in the form of stripes extending in the X direction and arrayed in the Y direction.

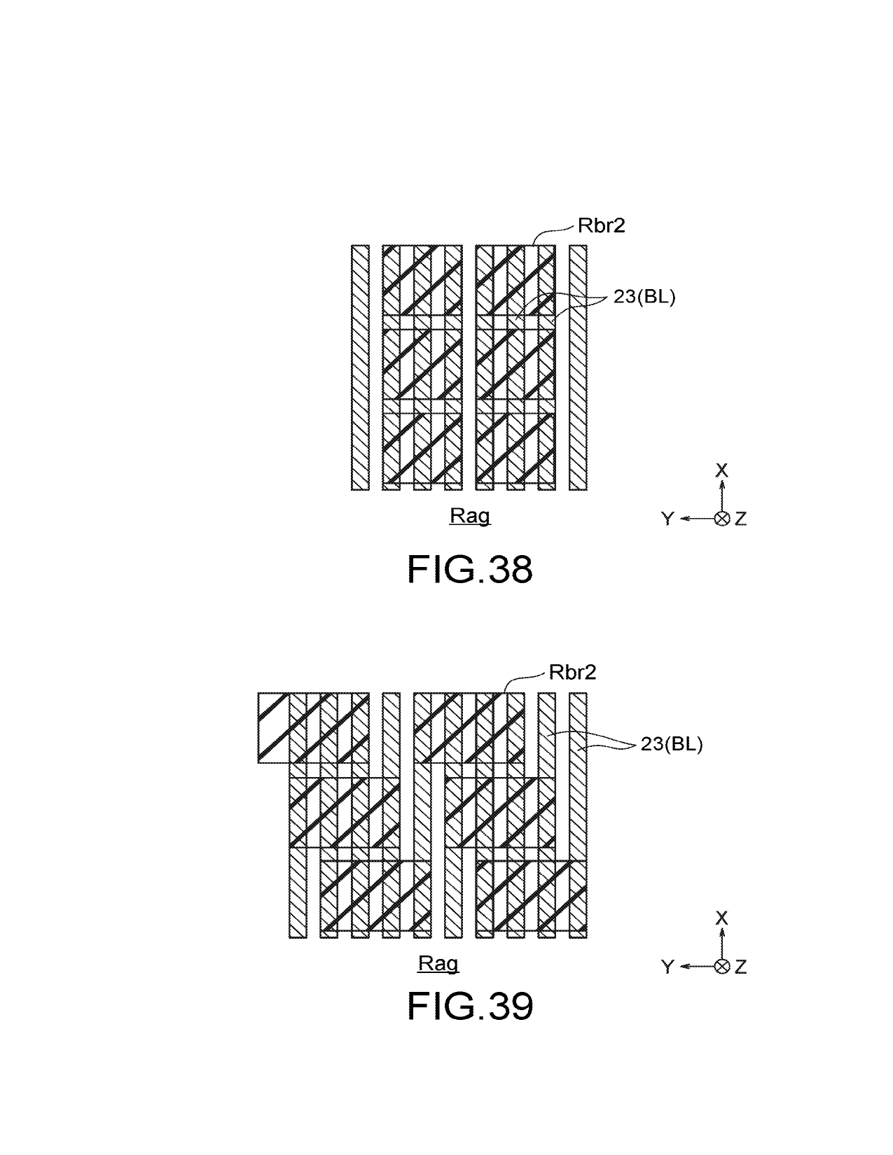

In FIG. 38, the buried regions Rbr2 have a layout in the form of islands arrayed in the X direction and the Y direction.

In FIG. 39, the buried regions Rbr2 have a layout in the form of islands arrayed in the Y direction and arranged to be shifted by one bit line BL in the X direction.

The layout of the buried regions Rbr2 may be the same as that of the buried regions Rbr1 or arrangement of the buried regions Rbr2 may be optionally changed as in these modifications. It suffices that the ratio in the area of the buried regions Rbr2 to the air gap region Rag is of a sufficient level to suppress sagging of the air gap region Rag and cracking of the substrate. Even when the ratio in the area of the buried regions Rbr2 to the air gap region Rag is different to some extent from the ratio in the area of the buried regions Rbr1 to the via formation region Rvia, the effect of suppressing sagging of the air gap region Rag and cracking of the substrate can be obtained. Also in the modifications of the fourth embodiment, the planar layout of the buried regions Rbr1 may be the same as that in the first embodiment or the second embodiment. That is, the planar layout of the buried regions Rbr1 in the modifications of the fourth embodiment may be in the form of stripes.

In order to reduce the capacitances between the bit lines BL, it is desirable that the areas of the buried regions Rbr1 and Rbr2 are as small as possible. On the other hand, to suppress cracking in the CMP process, a certain level of the areas of the buried regions Rbr1 and Rbr2 is required. Therefore, it is preferable to set the areas of the buried regions Rbr1 and Rbr2 to be as small as possible while suppressing cracking in the CMP process.

### Fifth embodiment

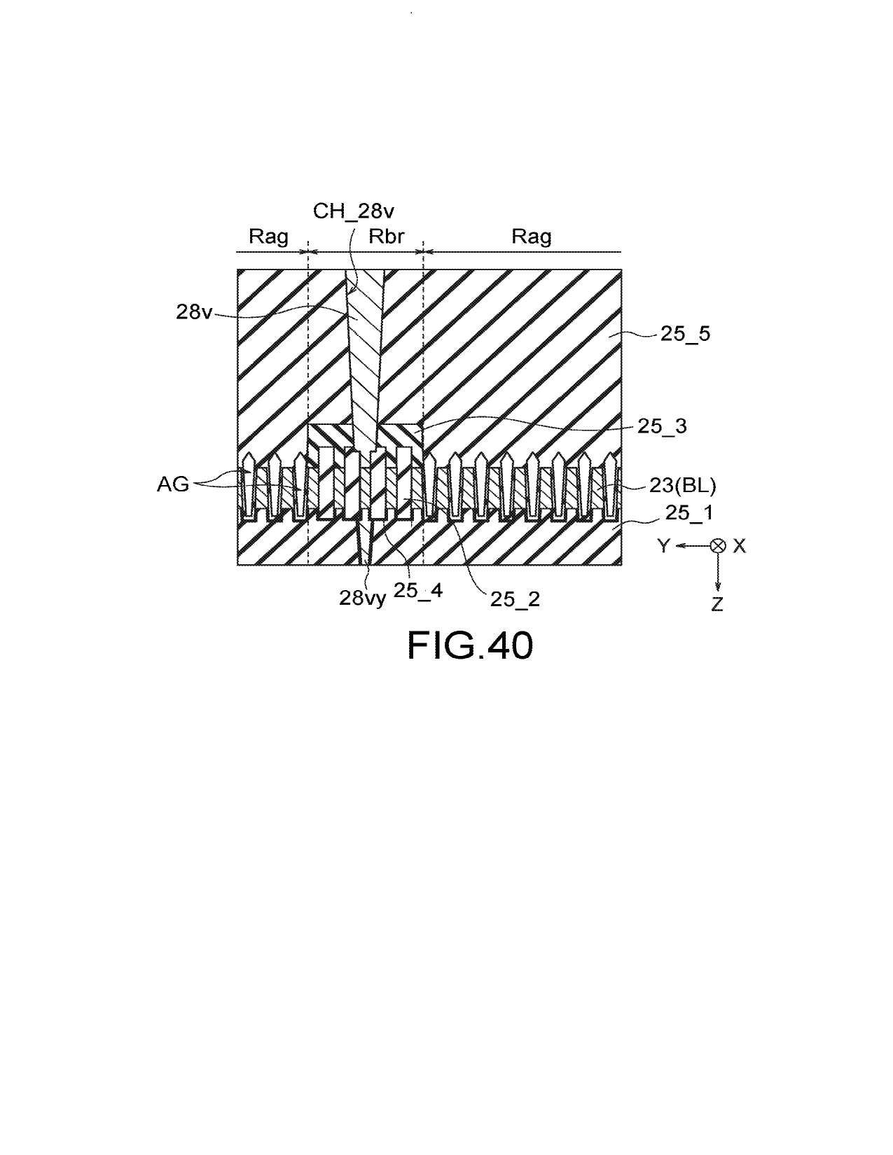

FIG. 40 is a sectional view illustrating a configuration example of a semiconductor memory device according to a fifth embodiment. The buried region Rbr of the fifth embodiment can have the same structure as that of the first embodiment. Meanwhile, in the air gap region Rag of the fifth embodiment, the third insulating film 25_3 is removed and the air gaps AG are provided in the fifth insulating film 25_5. The rest of the configuration in the fifth embodiment may be identical to that in the first embodiment.

A manufacturing method of the semiconductor memory device 1 according to the fifth embodiment is described next.

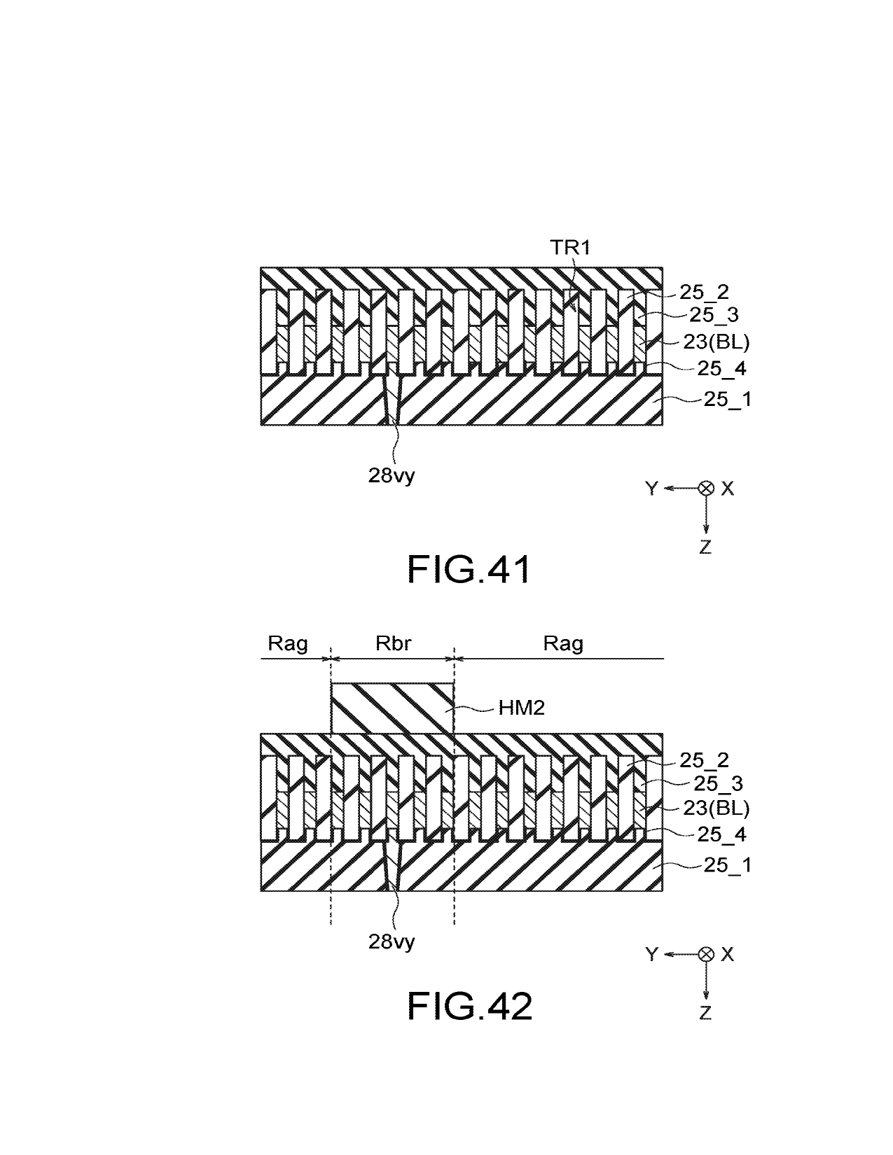

FIGS. 41 to 45 are sectional views illustrating one example of the manufacturing method of the semiconductor memory device according to the fifth embodiment. After the processes described with reference to FIGS. 10 to 12 are performed, the material of the third insulating film 25_3 is further deposited on the second insulating film 25_2.

Next, the material of the hard mask HM2 is deposited on the third insulating film 25_3. The material of the hard mask HM2 in the air gap region Rag is removed using a lithography technique and an etching technique to leave the hard mask HM2 in the buried region Rbr as illustrated in FIG. 42.

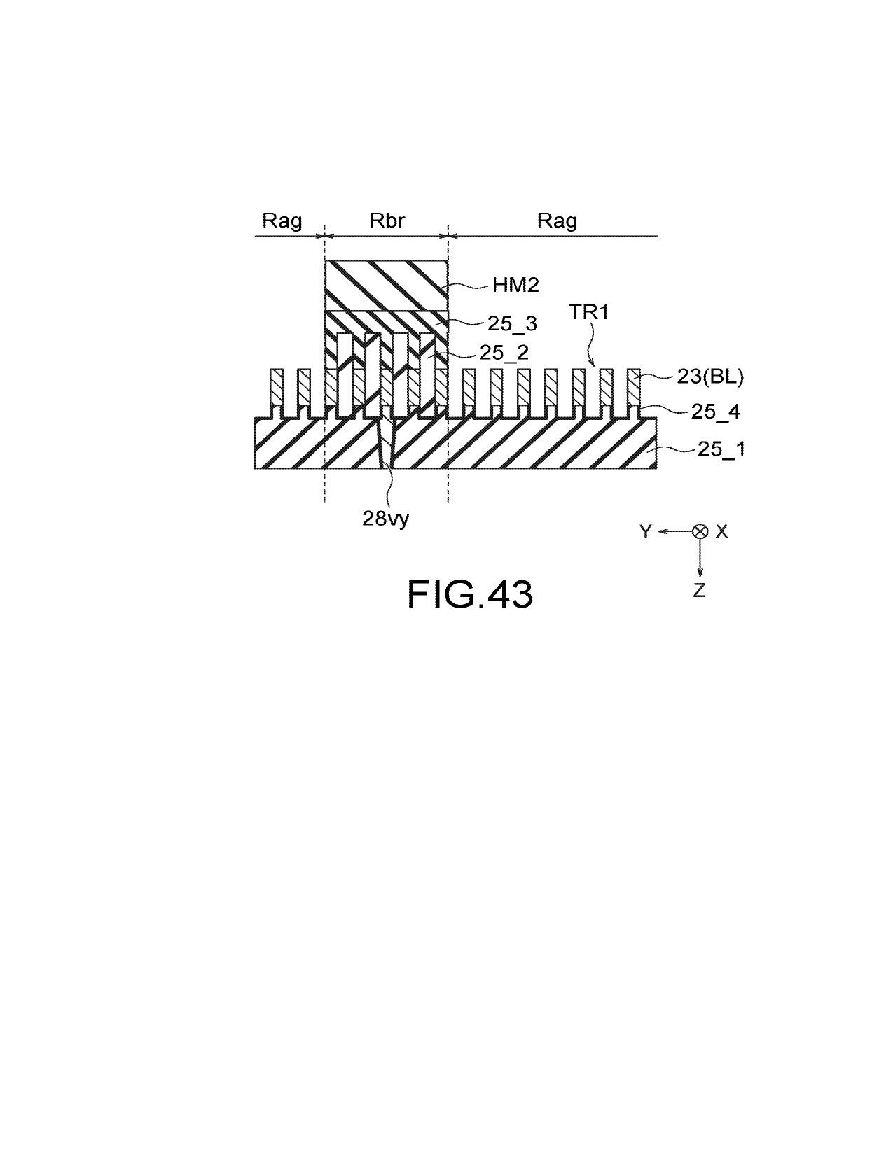

Next, as illustrated in FIG. 43, the third insulating film 25_3 and the second insulating film 25_2 in the air gap region Rag are selectively etched using the hard mask HM2 as a mask. At that time, the fourth insulating film 25_4 functions as an etching stopper in the air gap region Rag. Therefore, the trenches TR1 are formed to reach the fourth insulating film 25_4. Meanwhile, the second insulating film 25_2 in the buried region Rbr is left and the trenches TR1 are not formed.

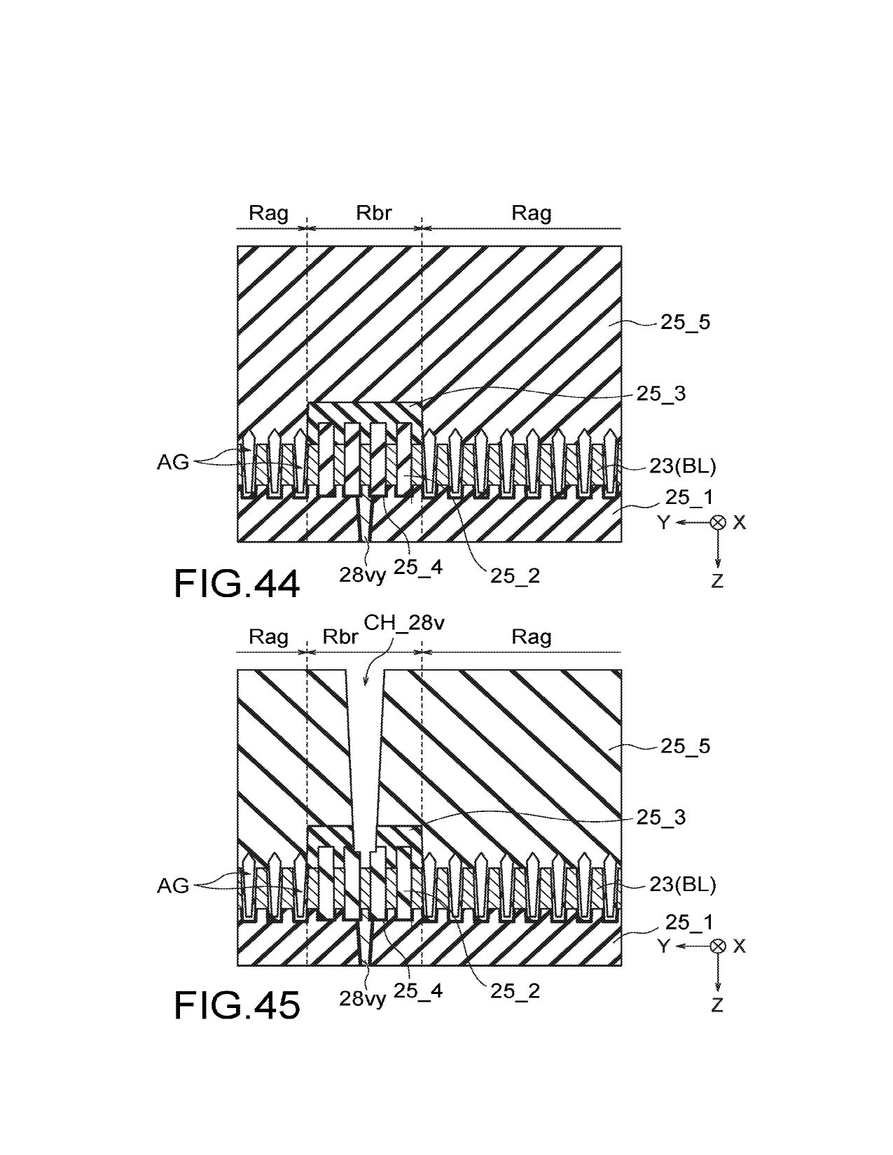

Next, after the hard mask HM2 is removed, the material (for example, a silicon nitride) of the fifth insulating film 25_5 is deposited on the third insulating film 25_3, the bit lines BL, and the trenches TR1 from the -Z direction as illustrated in FIG. 44. At that time, the material of the fifth insulating film 25_5 is deposited by the CVD method or the like on a condition where step coverage is decreased. Accordingly, in the air gap region Rag, the material of the fifth insulating film 25_5 closes the openings of the trenches TR1 and leaves an air gap AG in each thereof. The material of the fifth insulating film 25_5 is thinly formed on the inner walls and the bottom surfaces of the trenches TR1. Therefore, the fifth insulating film 25_5 is located between each of the bit lines BL and adjacent air gaps AG and between the first insulating film 25_1 and the air gaps AG. Meanwhile, since the second insulating film 25_2 is buried in the trenches TR1 in the buried region Rbr, no air gaps AG are formed.

Next, the contact holes CH_28v are formed at positions of the via contacts 28v using a lithography technique and an etching technique as illustrated in FIG. 45. The contact holes CH_28v are formed in the via formation region Rvia in the buried region Rbr. The contact holes CH_28v penetrate through the fifth insulating film 25_5 and the third insulating film 25_3 to reach the corresponding bit lines BL, respectively. At that time, in the buried region Rbr, no air gap AG is formed between the bit lines BL and a part between the bit lines BL is filled with the second insulating film 25_2. Therefore, a margin of the width of the second insulating film 25_2 is provided for misalignment of the contact holes CH_28v.

Meanwhile, in the air gap region Rag, the air gaps AG are formed between the bit lines BL. Therefore, the parasitic capacitances between the bit lines BL can be reduced. Accordingly, disturb of data between the bit lines BL can be suppressed.

Subsequently, the via contacts 28v are embedded in the contact holes CH_28v, respectively, whereby a structure illustrated in FIG. 40 is obtained.

As in the fifth embodiment, the fifth insulating film 25_5 is provided instead of the third insulating film 25_3 and the air gaps AG are provided in the fifth insulating film 25_5 in the air gap region Rag. Even with the configuration in the fifth embodiment, the same effects as those in the first embodiment can be obtained.

The fifth embodiment may be combined with the third or fourth embodiment. The planar layout of the fifth embodiment may be any layout of the modifications described above.

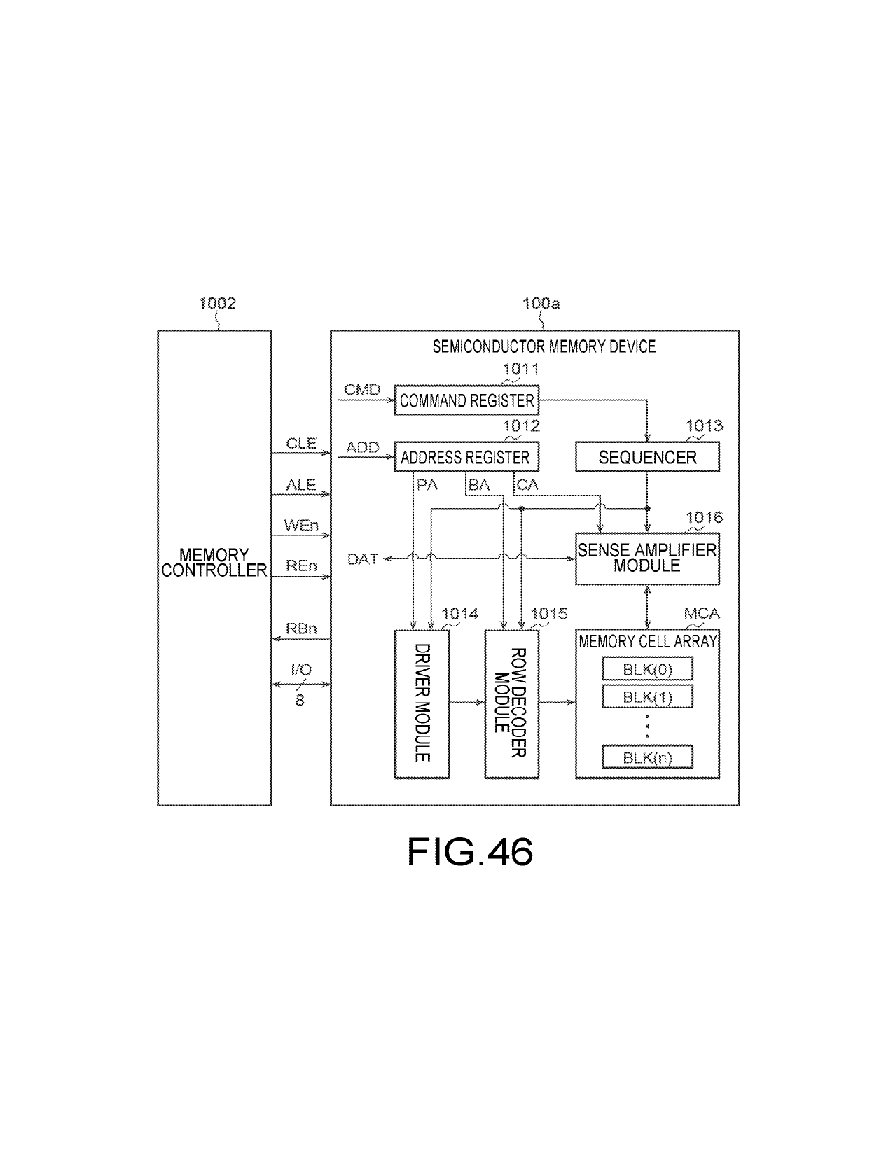

FIG. 46 is a block diagram illustrating a configuration example of a semiconductor memory device to which any of the array chips according to the embodiments described above is applied. The semiconductor memory device 1 is, for example, a memory 100a such as a NAND flash memory that can store therein data in a non-volatile manner and is controlled by an external memory controller 1002. Communications between the memory 100a and the memory controller 1002 are compliant with NAND interface standards, for example.

As illustrated in FIG. 46, the memory 100a includes, for example, a memory cell array MCA (2m), a command register 1011, an address register 1012, a sequencer 1013, a driver module 1014, a row decoder module 1015, and a sense amplifier module 1016.

The memory cell array MCA includes a plurality of blocks BLK(0) to BLK(n) (n is an integer equal to or greater than 1). Each of the blocks BLK is a set of a plurality of memory cells that each can store therein data in a nonvolatile manner and is used as, for example, a data erasing unit. A plurality of bit lines and a plurality of word lines are provided in the memory cell array MCA. Each memory cell is linked to, for example, one bit line and one word line. A detailed configuration of the memory cell array MCA will be described later.

The command register 1011 holds a command CMD received by the memory 100a from the memory controller 1002. The command CMD includes, for example, an instruction for causing the sequencer 1013 to perform an operation such as a read operation, a write operation, or an erase operation.

The address register 1012 holds address information ADD received by the memory 100a from the memory controller 1002. The address information ADD includes, for example, a block address BA, a page address PA, and a column address CA. For example, the block address BA, the page address PA, and the column address CA are used to select a block BLK, a word line, and a bit line, respectively.

The sequencer 1013 controls the whole operation of the memory 100a. For example, the sequencer 1013 controls the driver module 1014, the row decoder module 1015, the sense amplifier module 1016, and the like in accordance with the command CMD held by the command register 1011 to perform a read operation, a write operation, an erase operation, or the like.

The driver module 1014 generates a voltage to be used in a read operation, a write operation, an erase operation, or the like. The driver module 1014 applies the generated voltage, for example, to a signal line corresponding to a selected word line in accordance with the page address PA held in the address register 1012.

The row decoder module 1015 includes a plurality of row decoders. The row decoders select a corresponding one block BLK in the memory cell array MCA in accordance with the block address BA held by the address register 1012. The row decoders transfer, for example, the voltage applied to the signal line corresponding to the selected word line, to the selected word line in the selected block BLK.

The sense amplifier module 1016 applies a desired voltage to each of the bit lines according to data DAT to be written, which is received from the memory controller 1002, in a write operation. In a read operation, the sense amplifier module 1016 determines data stored in a memory cell on the basis of the voltage of a bit line and transfers a determination result to the memory controller 1002 as read data DAT.

The memory 100a and the memory controller 1002 described above may be combined to configure one semiconductor storage device. Examples of such a semiconductor storage device include a memory card such an SDTM card and an SSD (solid state drive).

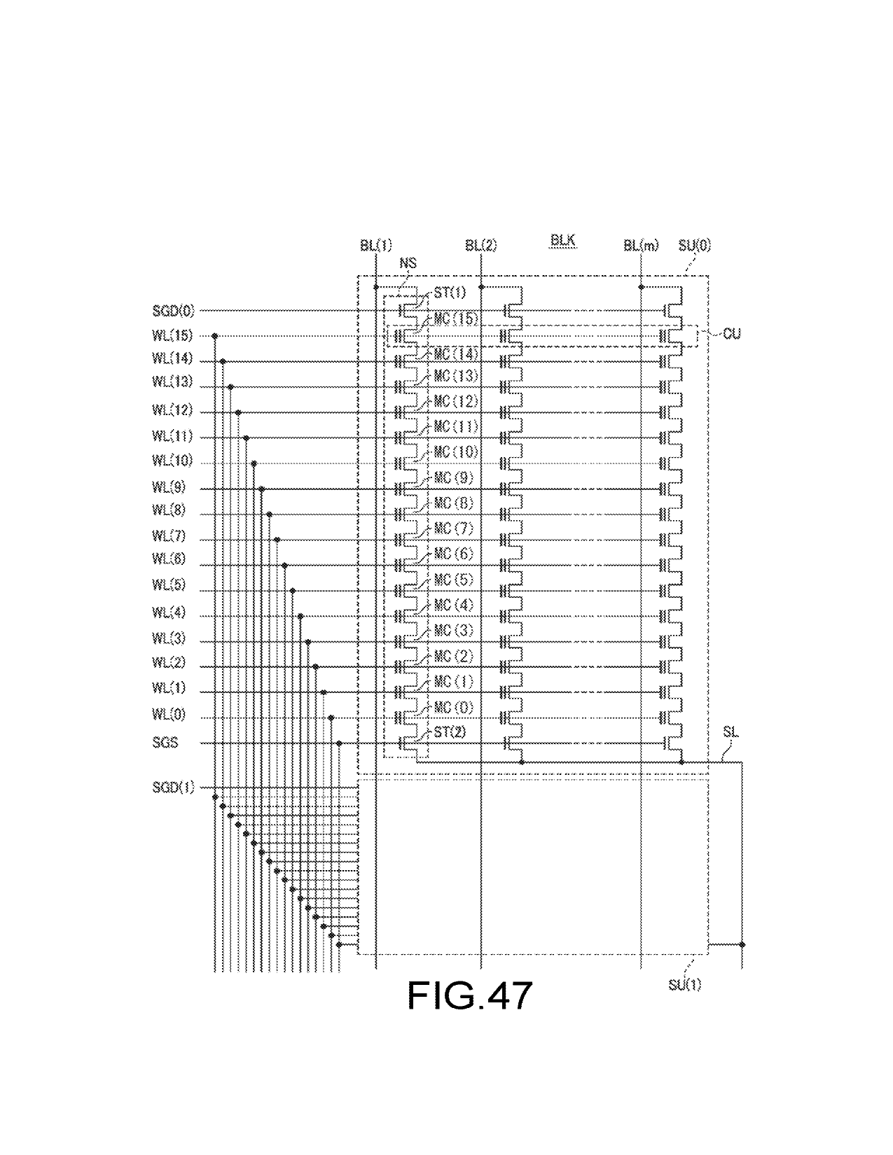

FIG. 47 is a circuit diagram illustrating one example of a circuit configuration of the memory cell array MCA. One block BLK out of the blocks BLK included in the memory cell array MCA is extracted. As illustrated in FIG. 47, each block BLK includes a plurality of string units SU(0) to SU(k) (k is an integer equal to or greater than 1).

Each string unit SU includes a plurality of NAND strings NS linked to bit lines BL(1) to BL(m) (m is an integer equal to or greater than 1), respectively. Each NAND string NS includes, for example, memory cells MC(0) to MC(15) and selection transistors ST(1) and ST(2). Each memory cell MC includes a control gate and a charge capturing layer and holds data in a nonvolatile manner. Each of the selection transistors ST(1) and ST(2) is used to select a string unit SU at the time of various operations.

In each NAND string NS, the memory cells MC(0) to MC(15) are connected in series. The drain of the selection transistor ST(1) is connected to the linked bit line BL and the source of the selection transistor ST(1) is connected to one end of the series-connected memory cells MC(0) to MC(15). The drain of the selection transistor ST(2) is connected to the other end of the series-connected memory cells MC(0) to MC(15). The source of the selection transistor ST(2) is connected to a source line SL.

In the same block BLK, control gates of the memory cells MC(0) to MC(15) are connected in common to word lines WL(0) to WL(15), respectively. The gates of the selection transistors ST(1) in each of the string units SU(0) to SU(k) are connected in common to an associated one of selection gate lines SGD(0) to SGD(k). The gates of the selection transistors ST(2) are connected in common to a selection gate line SGS.

In the circuit configuration of the memory cell array MCA described above, the bit lines BL are shared by NAND strings NS to which the same column address is allocated in each string unit SU. The source line SL is shared by, for example, a plurality of blocks BLK.

A set of memory cells MC connected to a common word line WL in one string unit SU is referred to as, for example, cell unit CU. For example, the memory capacity of the cell unit CU including the memory cells MC each storing therein 1-bit data is defined as "1-page data". The cell unit CU can have a memory capacity equal to or greater than 2-page data according to the number of bits of data stored in each memory cell MC.

The memory cell array MCA included in the memory 100a according to the present embodiment is not limited to the circuit configuration described above. For example, the numbers of the memory cells MC and the selection transistors ST(1) and ST(2) included in each NAND string NS can be designed to be any numbers. The number of the string units SU included in each block BLK can be designed to be any number.

The embodiments described above are also applicable to lines and via contacts of a logic circuit of a CMOS chip or the like, as well as the array chip of a memory.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a stacked body comprising a plurality of conductive layers and a plurality of insulating layers stacked alternately in a first direction;
a first insulating film located in the first direction with respect to the stacked body;
third lines located in the first direction with respect to the first insulating film, extending in a second direction intersecting with the first direction, being arrayed in a third direction intersecting with the first and second directions, and comprising a plurality of first lines and a plurality of second lines;
a fifth line located in the first direction with respect to a fourth line being any one of the plurality of first lines;
a first contact electrically connecting the fourth line and the fifth line;
a second insulating film located between a sixth line and the fourth line, the sixth line being another one of the plurality of first lines and being adjacent to the fourth line; and
a third insulating film located in the first direction with respect to the first insulating film, and having an air gap between adjacent two of the plurality of second lines, wherein
the first contact and the second insulating film are located in a first region as viewed from the first direction, and
the third insulating film is located in a second region different from the first region as viewed from the first direction.

2. The device of claim 1, wherein ends of the air gaps in the first direction are located at a position closer to the fifth line than ends of the second lines in the first direction.

3. The device of claim 1, wherein ends of the air gaps in an opposite direction to the first direction are located at a position closer to the first insulating film than ends of the second lines in the opposite direction to the first direction.

4. The device of claim 1, wherein the second insulating film is located between adjacent two of seventh lines in a peripheral region peripheral to a region where the stacked body is formed.

5. The device of claim 1, wherein the third insulating film is located between sidewalls of the second lines and the air gaps in the second region.

6. The device of claim 1, wherein the third insulating film is located between the first insulating film and the air gaps in the second region.

7. The device of claim 1, wherein a fourth insulating film connecting the fourth line and the sixth line is located between the first insulating film and the second insulating film in the first region.

8. The device of claim 4, wherein a fourth insulating film connecting adjacent two of seventh lines is located between the first insulating film and the second insulating film in a peripheral region peripheral to a region where the stacked body is formed.

9. The device of claim 1, wherein
the first region comprises a buried region where the second insulating film is located between the plurality of first lines, and
the buried region is located in a manner of stripes extending in the third direction and arrayed in the second direction as viewed from the first direction.

10. The device of claim 1, wherein
the first region comprises a buried region where the second insulating film is located between the plurality of first lines, and
the buried region is located to be associated with one or a plurality of the first contacts connected to the fourth line as viewed from the first direction.

11. The device of claim 10, wherein the buried region is located in a manner of an island to be associated with the first contacts as viewed from the first direction.

12. The device of claim 1, wherein the second insulating film is located in a third region being a part of the second region and is also located between adjacent two of the second lines as viewed from the first direction.

13. The device of claim 12, wherein the third region has a shape of stripes extending in the third direction and arrayed in the second direction as viewed from the first direction.

14. The device of claim 12, wherein the third region is located in a manner of an island to be associated with one or a number of the second lines as viewed from the first direction.

15. The device of claim 12, wherein the third region has a shape of stripes extending in the second direction and arrayed in the third direction as viewed from the first direction.

16. The device of claim 1, further comprising:
a plurality of columnar bodies each comprising a first semiconductor part extending in the first direction in the stacked body, and a first insulating part located between the first semiconductor part and the stacked body; and
a second contact penetrating through the first insulating film and connecting any one of the columnar bodies and any one of the third lines.

17. A manufacturing method of a semiconductor device, the method comprising:
forming a stacked body including a plurality of conductive layers and a plurality of insulating layers in a first direction;
forming a first insulating film in the first direction with respect to the stacked body;
forming third lines comprising a plurality of first lines and a plurality of second lines in a first region and a second region, the second region different from the first region as viewed from the first direction, the third lines being located in the first direction with respect to the first insulating film, the third line extending in a second direction intersecting with the first direction, and the third line being arrayed in a third direction intersecting with the first and second directions;
forming a second insulating film between the plurality of first lines;
removing the second insulating film in the second region to form first trenches between the plurality of second lines in the second region;
forming a third insulating film on the second insulating film in the first region, and in upper parts of the first trenches so as to form air gaps between the plurality of second lines in the second region;
forming a contact hole reaching to any one of the plurality of first lines in the third insulating film in the first region; and
forming a first contact electrically connecting to the any one of the plurality of first lines in the contact hole in the first region.
